(19) United States
(12) Patent Application Publication
(10) Pub. No.: US 2025/0283764 A1
(43) Pub. Date: Sep. 11, 2025

(54) SEMICONDUCTOR DEVICE AND ELECTRONIC SYSTEM INCLUDING THE SEMICONDUCTOR DEVICE

(71) Applicant: Samsung Electronics Co., Ltd., Suwon-si (KR)

(72) Inventors: JOONYONG KIM, Suwon-si (KR); IN JUN HWANG, Suwon-si (KR)

(21) Appl. No.: 18/815,008

(22) Filed: Aug. 26, 2024

(30) Foreign Application Priority Data
Mar. 11, 2024 (KR) 10-2024-0033977

(51) Int. Cl. G01K 7/01; H01L 29/20; H01L 29/778

(52) U.S. Cl. CPC G01K 7/01; H10D 30/475; H10D 62/8503

(57) ABSTRACT

A system comprising a semiconductor device including a main element area including a main channel layer and a barrier layer containing materials having different energy band gaps, a gate electrode, a gate semiconductor layer between the barrier layer and gate electrode, and source and drain electrodes on opposite sides of the gate electrode, and a peripheral circuit area including a channel pattern including drift regions having a two-dimensional electron gas, a power voltage electrode, and a sensing electrode, wherein the resistance of a first drift region between the source and sending electrodes has a positive temperature coefficient of resistance, and a first contact resistance between the power voltage electrode and the channel pattern has a negative temperature coefficient of resistance, and wherein a temperature calculator senses the temperature of the semiconductor device according to the ratio between the resistance of the first drift region and the first contact resistance.

### CROSS-REFERENCE TO RELATED APPLICATION(S)

This application claims priority to and the benefit thereof under 35 U.S.C. § 119 to Korean Patent Application No. 10-2024-0033977, filed in the Korean Intellectual Property Office on Mar. 11, 2024, the entire contents of which are incorporated herein by reference.

### BACKGROUND OF THE INVENTION

### 1. Field of the Invention

The present disclosure relates to a semiconductor device and an electronic system including the semiconductor device.

### 2. Description of the Related Art

In the modern society, semiconductor devices are closely related to our daily lives. In particular, power semiconductor devices are becoming increasingly important in various fields such as the transportation field, for example, electric vehicles, trains, and electric trams, renewable energy systems, for example, solar power generation and wind power generation, and mobile devices. Power semiconductor devices are semiconductor devices usable to handle high voltage or high current, and perform functions such as power conversion and control in large power systems and high-power electronic devices. Power semiconductor devices have the ability and durability to handle high power, allowing them to handle large amounts of current and withstand high voltages. For example, power semiconductor devices can handle voltages of hundreds to thousands of volts and currents of tens to thousands of amperes. Power semiconductor devices can improve the efficiency of electrical energy by minimizing power losses. Further, power semiconductor devices can be stably driven in environments such as high temperatures.

These power semiconductor devices can be categorized by their materials, and for example, there are SiC power semiconductor devices and GaN power semiconductor devices. Instead of conventional silicon (Si) wafers, SiC or GaN may be used to manufacture power semiconductor devices, whereby it is possible to compensate for the disadvantages of silicon having unstable characteristics at high temperatures. SiC power semiconductor devices are resistant to high temperatures and have low power loss, making them suitable for electric vehicles, renewable energy systems, and the like. GaN power semiconductor devices require high costs, but are efficient in terms of speed, making them suitable for fast charging of mobile devices and the like.

### SUMMARY OF THE INVENTION

The present disclosure attempts to provide a semiconductor device that has stable electrical characteristics and improved reliability, and an electronic system including the semiconductor device.

An electronic system comprising a semiconductor device, and a temperature calculator configured to detect a temperature of the semiconductor device, wherein the semiconductor device includes a main element area and a peripheral circuit area that is positioned on one side of the main element area, wherein the main element area includes a main channel layer, a barrier layer on the main channel layer and containing a material having an energy band gap different from that of the main channel layer, a gate electrode on the barrier layer, a gate semiconductor layer between the barrier layer and the gate electrode, and a source electrode and a drain electrode positioned on opposite sides of the gate electrode and connected to the main channel layer, and wherein the peripheral circuit area includes a channel pattern connected to the source electrode and including drift regions having a two-dimensional electron gas, a power voltage electrode on the channel pattern, and spaced apart from the source electrode, and configured to receive a sensing power voltage, and a sensing electrode on the channel pattern and between the source electrode and the power voltage electrode, and wherein a resistance of a first drift region of the channel pattern between the source electrode and the sensing electrode has a positive temperature coefficient of resistance, wherein a first contact resistance between the power voltage electrode and the channel pattern has a negative temperature coefficient of resistance, and wherein the temperature calculator is configured to receive a sensing voltage from the sensing electrode and sense the temperature of the semiconductor device according to a ratio between a resistance value of the first drift region and a value of the first contact resistance.

A semiconductor device comprising a main element area and a peripheral circuit area positioned on one side of the main element area, wherein the main element area includes a main channel layer, a barrier layer on the main channel layer and containing a material having an energy band gap different from that of the main channel layer, a gate electrode on the barrier layer, a gate semiconductor layer between the barrier layer and the gate electrode, and a source electrode and a drain electrode positioned on opposite sides of the gate electrode and connected to the main channel layer, and wherein the peripheral circuit area includes a channel pattern connected to the source electrode and including drift regions having a two-dimensional electron gas, a power voltage electrode on the channel pattern, and spaced apart from the source electrode, and configured to receive a sensing power voltage, and a sensing electrode on the channel pattern and between the source electrode and the power voltage electrode, and wherein a resistance of a first drift region of the channel pattern between the source electrode and the sensing electrode has a positive temperature coefficient of resistance, wherein a first contact resistance between the power voltage electrode and the channel pattern has a negative temperature coefficient of resistance, and wherein a width of the channel pattern is smaller than a width of the main channel layer, and a width of the sensing electrode is smaller than the width of the channel pattern.

An electronic system comprising a semiconductor device, and a temperature calculator configured to detect a temperature of the semiconductor device, wherein the semiconductor device includes a main element area and a peripheral circuit area positioned on one side of the main element area, wherein the main element area includes a main channel layer that contains GaN, a barrier layer on the main channel layer and containing AlGaN, a gate electrode on the barrier layer, a gate semiconductor layer between the barrier layer and the gate electrode, and containing GaN doped with a p-type impurity, a source electrode and a drain electrode positioned on opposite sides of the gate electrode and connected to the main channel layer, and a protective layer that covers the barrier layer and the gate electrode, and wherein the peripheral circuit area includes a channel pattern connected to the source electrode, containing the same material as that of the main channel layer, and including drift regions having a two-dimensional electron gas, a power voltage electrode on the channel pattern, containing the same material as that of the source electrode, and positioned apart from the source electrode, and a sensing electrode on the channel pattern and between the source electrode and the power voltage electrode, and wherein a resistance of a first drift region of the channel pattern between the source electrode and the sensing electrode has a positive temperature coefficient of resistance, wherein a first contact resistance between the power voltage electrode and the channel pattern has a negative temperature coefficient of resistance, and wherein the temperature calculator is configured to receive a sensing voltage from the sensing electrode and sense the temperature of the semiconductor device according to a ratio between the resistance value of the first drift region and a value of the first contact resistance.

According to the embodiments, it is possible to improve the electrical characteristics and reliability of the electronic systems including the semiconductor devices.

### BRIEF DESCRIPTION OF THE DRAWINGS

FIG. 1 is a plan view illustrating an electronic system including a semiconductor device according to an example embodiment.

FIGS. 2 and 3 are cross-sectional views taken along line A-A′ of FIG. 1.

FIG. 4 is a circuit diagram illustrating the electronic system including the semiconductor device according to the example embodiment.

FIG. 5 is a cross-sectional view taken along line B-B′ of FIG. 1.

FIG. 6 is a graph illustrating the degree of sensitivity of a temperature sensing circuit of the semiconductor device according to the example embodiment.

FIGS. 7 to 9 are plan views illustrating semiconductor devices according to some example embodiments.

FIG. 10 is a circuit diagram illustrating an electronic system including a semiconductor device according to some example embodiments.

FIG. 11 is a cross-sectional view that illustrates a semiconductor device according to some embodiments and corresponds to an area taken along line B-B′ of FIG. 1.

FIG. 12 is a circuit diagram illustrating an electronic system including a semiconductor device according to some example embodiments.

FIG. 13 is a plan view illustrating the semiconductor device according to some example embodiments.

FIG. 14 is a cross-sectional view taken along line C-C′ of FIG. 13.

FIG. 15 is a circuit diagram illustrating an electronic system including a semiconductor device according to some example embodiments.

FIG. 16 is a plan view illustrating the semiconductor device according to some example embodiments.

FIG. 17 is a cross-sectional view taken along line D-D′ of FIG. 16.

FIG. 18 is a circuit diagram illustrating an electronic system including a semiconductor device according to some example embodiments.

FIG. 19 is a plan view illustrating the semiconductor device according to some example embodiments.

FIGS. 20 and 21 are cross-sectional views taken along line E-E′ of FIG. 19.

FIG. 22 is a plan view illustrating the semiconductor device according to some example embodiments.

### DETAILED DESCRIPTION OF THE EMBODIMENTS

In the following detailed description, only certain embodiments have been shown and described, simply by way of illustration. The present invention can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity. It will be understood that when an element is referred to as “contacting” or “in contact with” another element (or using any form of the word “contact”), there are no intervening elements present at the point of contact.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

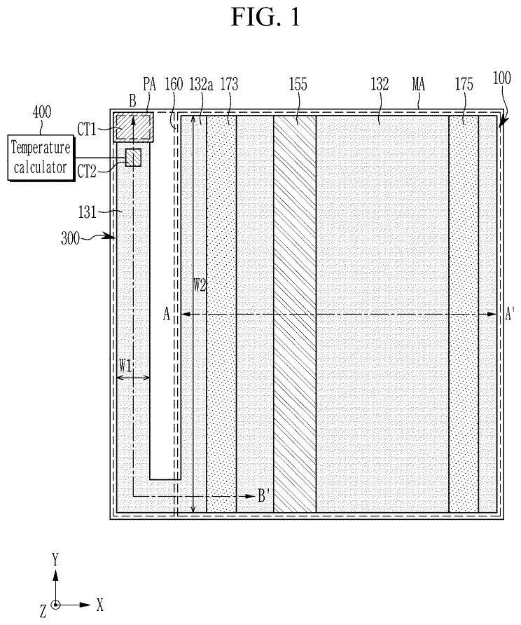

Hereinafter, a semiconductor device according to an embodiment will be described as follows with reference to FIGS. 1 to 3.

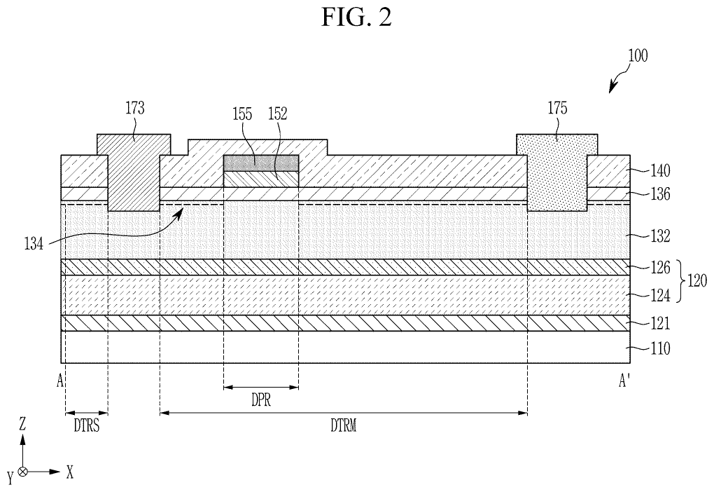

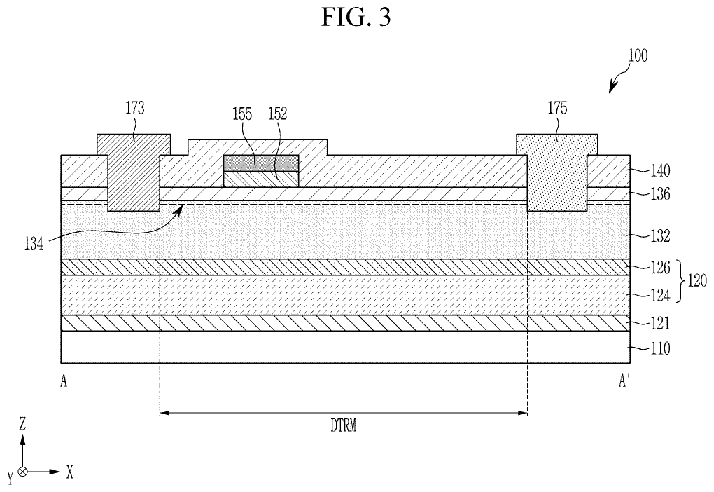

FIG. 1 is a plan view illustrating an electronic system including a semiconductor device according to an example embodiment. FIGS. 2 and 3 are cross-sectional views taken along line A-A′ of FIG. 1. FIG. 2 illustrates when the semiconductor device according to the embodiment is off, and FIG. 3 illustrates when the semiconductor device according to the embodiment is on.

First, as shown in FIG. 1, the semiconductor device according to the embodiment may include a main element area MA and a peripheral circuit area PA.

In the main element area MA, a main transistor 100 may be positioned. For example, the main transistor 100 of the semiconductor device according to the embodiment may be a normally-off high electron mobility transistor (HEMT). However, the main transistor 100 of the semiconductor device according to the embodiment is not limited thereto, and may be a normally-on high electron mobility transistor. In other words, in the embodiment, the main element area MA may refer to an area where the main transistor 100 is disposed.

Further, in the peripheral circuit area PA, elements which are electrically connected to the main transistor 100 may be included. For example, in the peripheral circuit area PA of the semiconductor device according to the embodiment, a temperature sensing circuit 300 that is electrically connected to the main transistor 100 may be positioned. In the embodiment, the temperature sensing circuit 300 may sense the temperature of the main transistor 100, and provide a sensing result signal to an external device, etc. Sensing the temperature of the main transistor 100 may include outputting an electrical signal corresponding to the temperature of the main transistor 100. The temperature sensing circuit 300 may be electrically connected to the main transistor 100. In the embodiment, the peripheral circuit area PA may refer to an area where the temperature sensing circuit 300 is disposed.

Although it has been described in the embodiment that the temperature sensing circuit 300 is positioned in the peripheral circuit area PA, the present disclosure is not limited thereto. For example, in the peripheral circuit area PA, passive elements such as resistors, capacitors, inductors, and the like may be positioned, and active elements such as transistors, diodes, integrated circuit (IC) chips, and the like also may be positioned. As another example, in the peripheral circuit area PA, current dividers, voltage dividers, voltage clippers, a protection element for the main transistor 100, and the like may be positioned.

In the embodiment, the peripheral circuit area PA may be positioned apart from the main element area MA. For example, as shown in FIG. 1, the peripheral circuit area PA may be positioned apart from the main element area MA in a second direction (a Y direction); however, the present disclosure is not limited thereto. For example, the peripheral circuit area PA may be positioned apart from the main element area MA in a first direction (an X direction), or may surround the side surface of the main element area MA. Of course, various other changes are possible. In the embodiment, a separation structure 160 may be positioned between the peripheral circuit area PA and the main element area MA; however, the present disclosure is not limited thereto.

Referring to FIG. 2 together, the main element area MA of the semiconductor device according to the embodiment may include a main channel layer 132, a barrier layer 136 that is positioned on the main channel layer 132, a gate electrode 155 that is positioned on the barrier layer 136, a gate semiconductor layer 152 that is positioned between the barrier layer 136 and the gate electrode 155, a protective layer 140 that is positioned on the barrier layer 136, and a source electrode 173 and a drain electrode 175 that are spaced apart from each other on the main channel layer 132.

The main channel layer 132 may be a layer that forms a channel between the source electrode 173 and the drain electrode 175, and inside the main channel layer 132, a 2-dimensional electron gas (2DEG) 134 may be positioned. The 2-dimensional electron gas 134 is a charge transfer model that is used in solid-state physics, and means a bunch of electrons that are tightly confined in two dimensions (for example, in directions on an x-y plane) such that they are free to migrate in the two dimensions but cannot migrate in the other dimensions (for example, in a z direction). In other words, the 2-dimensional electron gas 134 may exist in a form like a two-dimensional sheet in a three-dimensional space. Such 2-dimensional electron gases mainly appear in semiconductor heterojunction structures, and in the semiconductor device according to the embodiment, the 2-dimensional electron gas 134 may occur at the interface between the main channel layer 132 and the barrier layer 136. For example, the 2-dimensional electron gas 134 may occur at a portion inside the main channel layer 132 adjacent to the barrier layer 136.

The main channel layer 132 may contain at least one material selected from Ill-V materials such as nitrides containing Al, Ga, In, B, or a combination thereof. The main channel layer 132 may consist of a single layer or multiple layers. The main channel layer 132 may be formed of AlₓIn_{y}Ga_{1-x-y}N (wherein 0≤x≤1, 0≤y≤1, and x+y≤1). For example, the main channel layer 132 may contain AlN, GaN, InN, InGaN, AlGaN, AlInN, AlInGaN, or a combination thereof. The main channel layer 132 may be a layer doped with impurities, or may be a layer undoped with impurities. The thickness of the main channel layer 132 may be about hundreds of nm or less.

In the embodiment, the main channel layer 132 may include an extension portion 132a which is positioned on one side of the source electrode 173. The extension portion 132a may be positioned between the source electrode 173 and the temperature sensing circuit 300 of the peripheral circuit area PA. The extension portion 132a may refer to a portion of the main channel layer 132 that is positioned on one side of the source electrode 173.

The main channel layer 132 may be positioned on a substrate 110, and between the substrate 110 and the main channel layer 132, a seed layer 121 and a buffer layer 120 may be positioned. The substrate 110, the seed layer 121, and the buffer layer 120 may be layers necessary to form the main channel layer 132, and may be omitted in some cases. For example, when a substrate made of GaN is used as the main channel layer 132, at least one of the substrate 110, the seed layer 121, and the buffer layer 120 may be omitted. In consideration of the relatively high prices of substrates made of GaN, a substrate 110 made of Si may be used to grow a main channel layer 132 containing GaN. In this case, since the lattice structure of Si and the lattice structure of GaN are different, it may not be easy to grow the main channel layer 132 directly on the substrate 110. Therefore, a seed layer 121 and a buffer layer 120 may be first grown on the substrate 110, and then the main channel layer 132 may be grown on the buffer layer 120. Also, at least one of the substrate 110, the seed layer 121, and the buffer layer 120 may be removed from the final structure of the semiconductor device after being used in the manufacturing process.

The substrate 110 may contain a semiconductor material. For example, the substrate 110 may contain sapphire, Si, SiC, AlN, GaN, or a combination thereof. The substrate 110 may be a silicon-on-insulator (SOI) substrate. However, the material of the substrate 110 is not limited thereto, and every substrate which is generally used may be applied. In some cases, the substrate 110 may contain an insulating material. For example, several layers including the main channel layer 132 may be formed on a semiconductor substrate first, and then the semiconductor substrate may be removed and replaced with an insulating substrate.

The seed layer 121 may be positioned directly on the substrate 110. However, the present disclosure is not limited thereto, and between the substrate 110 and the seed layer 121, other predetermined layers may be further positioned. The seed layer 121 is a layer to serve as a seed for growing the buffer layer 120, and may be formed of a crystal lattice structure to be a seed for the buffer layer 120. The buffer layer 120 may be positioned directly on the seed layer 121. However, the present disclosure is not limited thereto, and between the seed layer 121 and the buffer layer 120, other predetermined layers may be further positioned. The seed layer 121 may contain at least one material selected from Ill-V materials such as nitrides containing Al, Ga, In, B, or a combination thereof. The seed layer 121 may be formed of AlₓIn_{y}Ga_{1-x-y}N (wherein 0≤x≤1, 0≤y≤1, and x+y≤1). For example, the seed layer 121 may contain AlN, GaN, InN, InGaN, AlGaN, AlInN, AlInGaN, or a combination thereof.

The buffer layer 120 may be positioned on the seed layer 121. The buffer layer 120 may be directly on the seed layer 121. The buffer layer 120 may be positioned between the seed layer 121 and the main channel layer 132. The buffer layer 120 may be a layer for mitigating differences in lattice constant and thermal expansion coefficient between the seed layer 121 and the main channel layer 132 or preventing parasitic current (leakage current) from flowing through the main channel layer 132. The buffer layer 120 may contain at least one material selected from Ill-V materials such as nitrides containing Al, Ga, In, B, or a combination thereof. The buffer layer 120 may be formed of AlₓIn_{y}Ga_{1-x-y}N (wherein 0≤x≤1, 0≤y≤1, and x+y≤1). For example, the buffer layer 120 may contain AlN, GaN, InN, InGaN, AlGaN, AlInN, AlInGaN, or a combination thereof.

The buffer layer 120 of the semiconductor device according to the embodiment may include a superlattice layer 124 that is positioned on the seed layer 121, and a high-resistivity layer 126 that is positioned on the superlattice layer 124. The superlattice layer 124 and the high-resistivity layer 126 may be sequentially positioned on the substrate 110.

The superlattice layer 124 may be positioned on the seed layer 121. The superlattice layer 124 may be positioned directly on the seed layer 121. However, the present disclosure is not limited thereto, and between the seed layer 121 and the superlattice layer 124, other predetermined layers may be further positioned. The superlattice layer 124 is a layer for migrating differences in lattice constant and thermal expansion coefficient between the substrate 110 and the main channel layer 132, thereby relieving tensile stress and compressive stress that is generated between the substrate 110 and the main channel layer 132 and relieving stress between all layers formed by growth in the final structure of the semiconductor device according to the embodiment. The superlattice layer 124 may contain at least one material selected from III-V materials such as nitrides containing Al, Ga, In, B, or a combination thereof. The superlattice layer 124 may be formed of AlₓIn_{y}Ga_{1-x-y}N (wherein 0≤x≤1, 0≤y≤1, and x+y≤1). For example, the superlattice layer 124 may contain AlN, GaN, InN, InGaN, AlGaN, AlInN, AlInGaN, or a combination thereof.

In the embodiment, the superlattice layer 124 may consist of multiple layers containing different materials and alternately stacked. For example, the superlattice layer 124 may have a structure in which layers consisting of AlGaN and layers consisting of AlN are alternately stacked. In other words, AlGaN, AlN, AlGaN, AlN, AlGaN, and AlN are sequentially stacked to form the superlattice layer. The numbers of AlGaN layers and AlN layers which constitute the superlattice layer 124 may be variously changed, and the materials which constitute the superlattice layer 124 may be variously changed. As another example, the superlattice layer 124 may have a structure in which layers consisting of AlGaN and layers consisting of GaN are alternately stacked. In other words, AlGaN, GaN, AlGaN, GaN, AlGaN, and GaN are sequentially stacked to form the superlattice layer. In the embodiment, when the superlattice layer 124 contains GaN, InN, AlGaN, AlInN, InGaN, AlN, AlInGaN, a combination thereof, etc., the superlattice layer 124 may have an n-type semiconductor characteristic in which the concentration of electrons is greater than the concentration of holes; however, the present disclosure is not limited thereto.

The high-resistivity layer 126 may be positioned on the superlattice layer 124. The high-resistivity layer 126 may be positioned directly on the superlattice layer 124. However, the present disclosure is not limited thereto, and between the superlattice layer 124 and the high-resistivity layer 126, other predetermined layers may be further positioned. The high-resistivity layer 126 may be positioned between the superlattice layer 124 and the main channel layer 132. The high-resistivity layer 126 is a layer for preventing leakage current from flowing through the main channel layer 132, thereby preventing the semiconductor device according to the embodiment from being deteriorated. The high-resistivity layer 126 may consist of a material having low conductivity such that the substrate 110 and the main channel layer 132 can be electrically insulated from each other. The high-resistivity layer may contain at least one material selected from Ill-V materials such as nitrides containing Al, Ga, In, B, or a combination thereof. The high-resistivity layer 126 may be formed of AlₓIn_{y}Ga_{1-x-y}N (wherein 0 x≤1, 0≤y≤1, and x+y≤1). For example, the high-resistivity layer 126 may contain AlN, GaN, InN, InGaN, AlGaN, AlInN, AlInGaN, or a combination thereof. The high-resistivity layer 126 may consist of a single layer or multiple layers. In the embodiment, when the high-resistivity layer 126 contains GaN, InN, AlGaN, AlInN, InGaN, AlN, AlInGaN, a combination thereof, etc., the high-resistivity layer 126 may have an n-type semiconductor characteristic in which the concentration of electrons is greater than the concentration of holes; however, the present disclosure is not limited thereto.

The barrier layer 136 may be positioned on the main channel layer 132. The barrier layer 136 may be positioned directly on the main channel layer 132. However, the present disclosure is not limited thereto, and between the main channel layer 132 and the barrier layer 136, other predetermined layers may be further positioned. A region of the main channel layer 132 overlapping the barrier layer 136 between the source electrode 173 and the drain electrode 175 may become a main drift region DTRM. The main drift region DTRM may be positioned between the source electrode 173 and the drain electrode 175. The main drift region DTRM may refer to a region in which carriers migrate when a potential difference occurs between the source electrode 173 and the drain electrode 175. Also, between the source electrode 173 of the main element area MA according to the embodiment and the temperature sensing circuit 300 of the peripheral circuit area PA, a sub drift region DTRS may be further included. In other words, a region of the extension portion 132a of the main channel layer 132 overlapping the barrier layer 136 may become the sub drift region DTRS. The sub drift region DTRS may refer to a region through which carriers migrate when a potential difference occurs between the source electrode 173 and an electrode of the peripheral circuit area PA (for example, a power voltage electrode CT1).

The semiconductor device according to the embodiment may be turned on and off according to at least one of whether voltage is applied to the gate electrode 155 and the magnitude of voltage which is applied to the gate electrode 155, whereby migration of carriers in the main drift region DTRM may be enabled or blocked.

The barrier layer 136 may contain at least one material selected from Ill-V materials such as nitrides containing Al, Ga, In, B, or a combination thereof. The barrier layer 136 may be formed of AlₓIn_{y}Ga_{1-x-y}N (wherein 0≤x≤1, 0≤y≤1, and x+y≤1). The barrier layer 136 may contain GaN, InN, AlGaN, AlInN, InGaN, AlN, AlInGaN, a combination thereof, etc. The energy band gap of the barrier layer 136 may be adjusted by the composition ratio of at least one of Al and In. The barrier layer 136 may be doped with a predetermined impurity. In this case, the impurity with which the barrier layer 136 is doped may be a p-type dopant capable of providing holes. For example, the impurity with which the barrier layer 136 is doped may be magnesium (Mg). By increasing or decreasing the concentration of the impurity with which the barrier layer 136 is doped, the threshold voltage, impedance, and the like of the semiconductor device according to the embodiment may be adjusted.

The barrier layer 136 may contain a semiconductor material having different characteristics from those of the main channel layer 132. At least one of the polarization characteristics, energy band gap, and lattice constant of the barrier layer 136 may be different from that of the main channel layer 132. For example, the barrier layer 136 may contain a material having an energy band gap different from that of the main channel layer 132. In this case, the barrier layer 136 may have an energy band gap higher than that of the main channel layer 132, and may have electrical polarizability higher than that of the main channel layer 132. By this barrier layer 136, the 2-dimensional electron gas 134 may be induced in the main channel layer 132 having relatively low electrical polarizability. In this regard, the barrier layer 136 may be referred to as a channel supply layer or a 2-dimensional electron gas supply layer. The 2-dimensional electron gas 134 may be formed in a portion of the main channel layer 132 positioned below the interface between the main channel layer 132 and the barrier layer 136. The 2-dimensional electron gas 134 may have very high electron mobility.

The barrier layer 136 may consist of a single layer or multiple layers. When the barrier layer 136 consists of multiple layers, the materials of the individual layers constituting the multiple layers may have different energy band gaps. In this case, the multiple layers constituting the barrier layer 136 may be disposed such that a layer closer to the main channel layer 132 has a higher energy band gap.

The gate electrode 155 may be positioned on the barrier layer 136. The gate electrode 155 may overlap a partial region of the barrier layer 136 in a vertical direction (for example, the thickness direction of the main channel layer 132). The gate electrode 155 may overlap a portion of the main drift region DTRM of the main channel layer 132 in the vertical direction (for example, the thickness direction of the main channel layer 132). The gate electrode 155 may be positioned between the source electrode 173 and the drain electrode 175. The gate electrode 155 may be spaced apart from the source electrode 173 and the drain electrode 175. For example, the gate electrode 155 may be positioned closer to the source electrode 173 than to the drain electrode 175. In other words, the separation distance between the gate electrode 155 and the source electrode 173 may be smaller than the separation distance between the gate electrode 155 and the drain electrode 175; however, the present disclosure is not limited thereto.

The gate electrode 155 may contain a conductive material. For example, the gate electrode 155 may contain a metal, a metal alloy, a conductive metal nitride, a metal silicide, a doped semiconductor material, a conductive metal oxide, a conductive metal oxynitride, or the like. For example, the gate electrode 155 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAI), titanium aluminum carbo-nitride (TiAlC—N), titanium aluminum carbide (TiAlC), titanium carbide (TiC), tantalum carbo-nitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The gate electrode 155 may consist of a single layer or multiple layers.

The gate semiconductor layer 152 may be positioned between the barrier layer 136 and the gate electrode 155. In other words, the gate semiconductor layer 152 may be positioned on the barrier layer 136, and the gate electrode 155 may be positioned on the gate semiconductor layer 152. For example, the gate semiconductor layer 152 may contact an upper surface of the barrier layer 136, and the gate electrode 155 may contact an upper surface of the gate semiconductor layer 152. The gate electrode 155 may be brought into Schottky contact or ohmic contact with the gate semiconductor layer 152. The gate semiconductor layer 152 may overlap the gate electrode 155 in the vertical direction (for example, the thickness direction of the main channel layer 132). In this case, the gate semiconductor layer 152 may completely overlap the gate electrode 155 in the vertical direction (for example, the thickness direction of the main channel layer 132), and the upper surface of the gate semiconductor layer 152 may be entirely covered by the gate electrode 155. In other words, the gate semiconductor layer 152 may have substantially the same plane shape as that of the gate electrode 155. However, the present disclosure is not limited thereto, and the gate electrode 155 may be positioned so as to cover at least a portion of the gate semiconductor layer 152.

The gate semiconductor layer 152 may be positioned between the source electrode 173 and the drain electrode 175. The gate semiconductor layer 152 may be spaced apart from the source electrode 173 and the drain electrode 175. The gate semiconductor layer 152 may be positioned closer to the source electrode 173 than to the drain electrode 175. In other words, the separation distance between the gate semiconductor layer 152 and the source electrode 173 may be smaller than the separation distance between the gate semiconductor layer 152 and the drain electrode 175; however, the present disclosure is not limited thereto.

In the embodiment, the gate semiconductor layer 152 may overlap the gate electrode 155 in the vertical direction (for example, the thickness direction of the main channel layer 132). For example, the gate semiconductor layer 152 may completely overlap the gate electrode 155 in the vertical direction (for example, the thickness direction of the main channel layer 132). In other words, the side surface of the gate semiconductor layer 152 may be aligned with the side surface of the gate electrode 155. However, the present disclosure is not limited thereto, and the gate semiconductor layer 152 may partially overlap the gate electrode 155.

The gate semiconductor layer 152 may contain at least one material selected from Ill-V materials such as nitrides containing Al, Ga, In, B, or a combination thereof. The gate semiconductor layer 152 may be formed of AlₓIn_{y}Ga_{1-x-y}N (wherein 0≤x≤1, 0≤y≤1, and x+y≤1). For example, the gate semiconductor layer 152 may contain AlN, GaN, InN, InGaN, AlGaN, AlInN, AlInGaN, or a combination thereof. The gate semiconductor layer 152 may contain a material having an energy band gap different from that of the barrier layer 136. For example, the gate semiconductor layer 152 may contain GaN, and the barrier layer 136 may contain AlGaN. The gate semiconductor layer 152 may be doped with a predetermined impurity. In this case, the impurity with which the gate semiconductor layer 152 is doped may be a p-type dopant capable of providing holes. For example, the gate semiconductor layer 152 may contain GaN doped with a p-type impurity. In other words, the gate semiconductor layer 152 may consist of a p-GaN layer. However, the gate semiconductor layer 152 is not limited thereto, and may be a p-AlGaN layer. The impurity with which the gate semiconductor layer 152 is doped may be magnesium (Mg). In this case, when the impurity (for example, magnesium) implanted into the gate semiconductor layer 152 is combined with some elements adjacent thereto, the hole concentration in the gate semiconductor layer 152 may decrease, and thus the characteristics of the semiconductor device may deteriorate. The gate semiconductor layer 152 may consist of a single layer or multiple layers.

By the gate semiconductor layer 152, a depletion region DPR may be formed inside the main channel layer 132. The depletion region DPR may be positioned inside the main drift region DTRM, and may have a width smaller than that of the main drift region DTRM. As the gate semiconductor layer 152 having an energy band gap different from that of the barrier layer 136 is positioned on the barrier layer 136, the level of the energy band of a portion of the barrier layer 136 overlapping the gate semiconductor layer 152 may be raised. Accordingly, the depletion region DPR may be formed in the main channel layer 132 overlapping the gate semiconductor layer 152. For example, the depletion region DPR may be positioned below the gate semiconductor layer 152. The depletion region DPR may be a region on the channel path of the main channel layer 132 where the 2-dimensional electron gas 134 is not formed or which has an electron concentration lower than that of the other regions. In other words, the depletion region DPR may refer to a region in the main drift region DTRM where the flow of the 2-dimensional electron gas 134 is cut. As the depletion region DPR is generated, no current may flow between the source electrode 173 and the drain electrode 175, and the channel path may be blocked. Accordingly, the semiconductor device according to the embodiment may have a normally-off characteristic.

In other words, the semiconductor device according to the embodiment may be a normally-off high electron mobility transistor (HEMT). As shown in FIG. 2, in a normal state in which voltage is not applied to the gate electrode 155, the depletion region DPR may exist, and the semiconductor device according to the embodiment may be off. As shown in FIG. 3, when a voltage equal to or higher than a threshold voltage is applied to the gate electrode 155, the depletion region DPR may disappear, and the 2-dimensional electron gas 134 may continue inside the main drift region DTRM, without being cut. In other words, the 2-dimensional electron gas 134 may be formed over the entire channel path between the source electrode 173 and the drain electrode 175, and the semiconductor device according to the embodiment may be turned on. In summary, the semiconductor device according to the embodiment may include semiconductor layers having different electrical polarization characteristics, and a semiconductor layer having relatively high polarizability may cause the 2-dimensional electron gas 134 in another semiconductor layer forming a heterojunction with it. This 2-dimensional electron gas 134 may be used as a channel between the source electrode 173 and the drain electrode 175, and the continuation or interruption of the flow of the 2-dimensional electron gas 134 may be controlled by a bias voltage that is applied to the gate electrode 155. In the gate-off state, the flow of the 2-dimensional electron gas 134 may be blocked, whereby no current flows between the source electrode 173 and the drain electrode 175. In the gate-on state, as the flow of the 2-dimensional electron gas 134 continues, current may flow between the source electrode 173 and the drain electrode 175.

Although it has been described above that the semiconductor device according to the embodiment is a normally-off high electron mobility transistor, the present disclosure is not limited thereto. For example, the semiconductor device according to the embodiment may be a normally-on high electron mobility transistor. When the semiconductor device is a normally-on high electron mobility transistor, the gate semiconductor layer 152 may be omitted, whereby the gate electrode 155 may be positioned directly on the barrier layer 136. In other words, the gate electrode 155 may be in contact with the barrier layer 136. In this structure, in a state where no voltage is applied to the gate electrode 155, the 2-dimensional electron gas 134 may be used as a channel, and a flow of current may occur between the source electrode 173 and the drain electrode 175. Further, when a negative voltage is applied to the gate electrode 155, the depletion region DPR where the flow of the 2-dimensional electron gas 134 is cut off may occur under the gate electrode 155.

The seed layer 121, the superlattice layer 124, the high-resistivity layer 126, the main channel layer 132, the barrier layer 136, and the gate semiconductor layer 152 described above may be sequentially stacked on the substrate 110. In the semiconductor device according to the embodiment, at least one of the seed layer 121, the superlattice layer 124, the high-resistivity layer 126, the main channel layer 132, the barrier layer 136, and the gate semiconductor layer 152 may be omitted. The seed layer 121, the superlattice layer 124, the high-resistivity layer 126, the main channel layer 132, the barrier layer 136, and the gate semiconductor layer 152 may consist of semiconductor materials based on the same materials, and the material composition ratios of the individual layers may be different from one another in view of the roles of the individual layers, the performance required for the semiconductor device, and the like.

The protective layer 140 may be positioned on the barrier layer 136 and the gate electrode 155. The protective layer 140 may cover the upper surface and side surface of the gate electrode 155 and the side surface of the gate semiconductor layer 152. The lower surface of the protective layer 140 may be in contact with the barrier layer 136 and the gate electrode 155. Accordingly, the barrier layer 136, the gate semiconductor layer 152, and the gate electrode 155 may be protected by the protective layer 140. However, the present disclosure is not limited thereto, and the gate electrode 155 may pass through the protective layer 140 and be connected to the gate semiconductor layer 152, and the protective layer 140 may not cover the upper surface of the gate electrode 155. Also, the lower surface of the protective layer 140 may be in contact with the gate semiconductor layer 152. The protective layer 140 may contain an insulating material. For example, the protective layer 140 may contain an oxide such as SiO₂, Al₂O₃, etc. As another example, the protective layer 140 may contain a nitride such as SiN, or an oxynitride such as SiON.

It is shown in FIGS. 2 and 3 that the protective layer 140 consists of a single layer. However, the protective layer 140 is not limited thereto, and may consist of multiple layers containing different materials.

The source electrode 173 and the drain electrode 175 may be positioned on the main channel layer 132. The source electrode 173 and the drain electrode 175 may be in direct contact with the main channel layer 132, and may be electrically connected to the main channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 may be spaced apart from the source electrode 173 and the drain electrode 175. For example, the source electrode 173 may be electrically connected to the main channel layer 132 on one side of the gate electrode 155, and the drain electrode 175 may be electrically connected to the main channel layer 132 on the other side of the gate electrode 155. The source electrode 173 and the drain electrode 175 may be positioned on the outside of the main drift region DTRM of the main channel layer 132. The interface between the source electrode 173 and the main channel layer 132 may be one edge of the main drift region DTRM. Similarly, the interface between the drain electrode 175 and the main channel layer 132 may be the other edge of the main drift region DTRM.

However, the present disclosure is not limited thereto, and the source electrode 173 and the drain electrode 175 may not be positioned on the outer surface of the main drift region DTRM of the main channel layer 132. In other words, the main channel layer 132 may not be recessed, and the source electrode 173 and the drain electrode 175 may be positioned on the upper surface of the main channel layer 132. In this case, the bottom surfaces of the source electrode 173 and the drain electrode 175 may be in contact with the upper surface of the main channel layer 132. The portions of the main channel layer 132 that are in contact with the source electrode 173 and the drain electrode 175 might have been doped at a high concentration. In this case, carriers passing through the 2-dimensional electron gas 134 may be transferred to the source electrode 173 and the drain electrode 175 through the portions of the main channel layer 132 doped at the high concentration, i.e., the upper portions of the 2-dimensional electron gas 134. The source electrode 173 and the drain electrode 175 may not be in direct contact with the 2-dimensional electron gas 134 in a horizontal direction. Here, the horizontal direction may refer to a direction parallel with the upper surface of the main channel layer 132 or the barrier layer 136.

Specifically, trenches that are formed so as to pass through the protective layer 140, the barrier layer 136 and portions of the upper surface of the main channel layer 132 may be positioned on opposite sides of the gate electrode 155 so as to be spaced apart from each other. Inside the trenches positioned on opposite sides of the gate electrode 155, the source electrode 173 and the drain electrode 175 may be positioned, respectively. The source electrode 173 and the drain electrode 175 may be formed so as to fill the trenches. Inside the trenches, the source electrode 173 and the drain electrode 175 may be in contact with the main channel layer 132 and the barrier layer 136. The main channel layer 132 may constitute the bottom surfaces and side walls of the trenches, and the barrier layer 136 may constitute the side walls of the trenches. Therefore, the source electrode 173 and the drain electrode 175 may be in contact with the upper surface and side surface of the main channel layer 132. Further, the source electrode 173 and the drain electrode 175 may be in contact with the side surface of the barrier layer 136. In other words, the source electrode 173 and the drain electrode 175 may cover the side surfaces of the main channel layer 132 and the barrier layer 136.

In the embodiment, the source electrode 173 and the drain electrode 175 may cover at least a portion of the side surface of the protective layer 140. For example, the source electrode 173 and the drain electrode 175 may cover the side surface of the protective layer 140. The upper surfaces of the source electrode 173 and the drain electrode 175 may protrude from the upper surface of the protective layer 140. In example embodiments, the upper surfaces of the source electrode 173 and the drain electrode 175 may be at a higher vertical level than the uppermost upper surface of the protective layer 140. Further, at least one of the source electrode 173 and the drain electrode 175 may cover at least a portion of the upper surface of the protective layer 140. For example, the source electrode 173 and the drain electrode 175 may contact at least a portion of the side surface of the protective layer 140. However, the source electrode 173 and the drain electrode 175 are not limited thereto, and may cover at least a portion of the side surface of the protective layer 140 and may not cover the other portion of the side surface of the protective layer 140. In this case, the other portion of the protective layer 140 may be positioned on the upper surfaces of the source electrode 173 and the drain electrode 175.

The source electrode 173 and the drain electrode 175 may contain a conductive material. For example, the source electrode 173 and the drain electrode 175 may contain a metal, a metal alloy, a conductive metal nitride, a metal silicide, a doped semiconductor material, a conductive metal oxide, a conductive metal oxynitride, or the like. For example, the source electrode 173 and the drain electrode 175 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAI), titanium aluminum carbo-nitride (TiAlC—N), titanium aluminum carbide (TiAlC), titanium carbide (TiC), tantalum carbo-nitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The source electrode 173 and the drain electrode 175 may consist of a single layer or multiple layers. The source electrode 173 and the drain electrode 175 may be in ohmic contact with the main channel layer 132. The regions in the main channel layer 132 which are in contact with the source electrode 173 and the drain electrode 175 may be doped at a relatively higher concentration as compared to the other region.

In FIGS. 1 to 3, it is shown that the semiconductor device according to the embodiment includes one pair of source electrode 173 and drain electrode 175; however, the numbers of source electrodes 173 and drain electrodes 175 are not limited thereto. For example, the source electrode 173 may include a plurality of source electrodes 173 sequentially stacked in the vertical direction (for example, the thickness direction of the main channel layer 132) on the main channel layer 132, and the drain electrode 175 may include a plurality of drain electrodes 175 sequentially stacked in the vertical direction (for example, the thickness direction of the main channel layer 132) on the main channel layer 132. Alternatively, each of the source electrode 173 and the drain electrode 175 may include three or more layers.

Although not shown in the drawings, the semiconductor device according to the embodiment may further include a field dispersion layer that covers at least a portion of the protective layer 140.

The field dispersion layer may be positioned between the source electrode 173 and the drain electrode 175. The field dispersion layer may cover the gate electrode 155. The field dispersion layer may overlap the gate electrode 155 in the vertical direction (for example, the thickness direction of the main channel layer 132). The field dispersion layer may be electrically connected to the source electrode 173. For example, the field dispersion layer may be connected to the source electrode 173. The field dispersion layer may contain the same material as that of the source electrode 173, and may be positioned together with the source electrode 173 in the same layer. The field dispersion layer may be formed together with the source electrode 173 in the same process. In other words, the boundary between the field dispersion layer and the source electrode 173 may not be clear, and the field dispersion layer may be formed integrally with the source electrode 173. However, the field dispersion layer is not limited thereto, and may be an individual constituent element separated from the source electrode 173. Also, the field dispersion layer and the source electrode 173 may be positioned in different layers, respectively, and may be formed in different processes, respectively.

The field dispersion layer may serve to disperse an electric field concentrated around the gate electrode 155. Specifically, in the gate-off state, the 2-dimensional electron gas 134 may be positioned with a very high concentration in the portion of the main channel layer 132 positioned between the gate electrode 155 and the source electrode 173 and the portion of the main channel layer 132 positioned between the gate electrode 155 and the drain electrode 175. In this case, the electric field may be concentrated on the gate electrode 155 or the gate semiconductor layer 152. Meanwhile, since the gate electrode 155 and the gate semiconductor layer 152 are vulnerable to electric fields, when an electric field is concentrated on them, leakage current may increase, and the breakdown voltage may decrease. In this case, the electric field concentrated around the gate electrode 155 or the gate semiconductor layer 152 may be dispersed by the field dispersion layer, whereby leakage current may be reduced and the breakdown voltage may be increased.

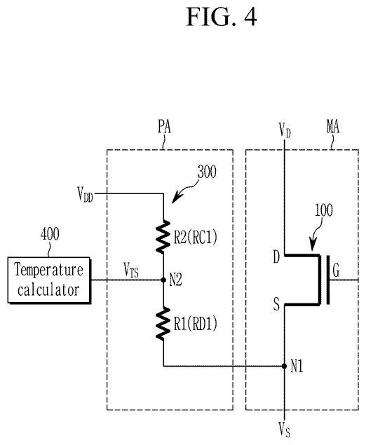

Hereinafter, the circuit structure of the electronic system including the semiconductor device according to the embodiment will be described with reference to FIG. 4.

FIG. 4 is a circuit diagram illustrating the electronic system including the semiconductor device according to the embodiment.

Referring to FIG. 4, the electronic system according to the embodiment may include the semiconductor device and a temperature calculator 400, and the semiconductor device according to the embodiment may include the main transistor 100 and the temperature sensing circuit 300.

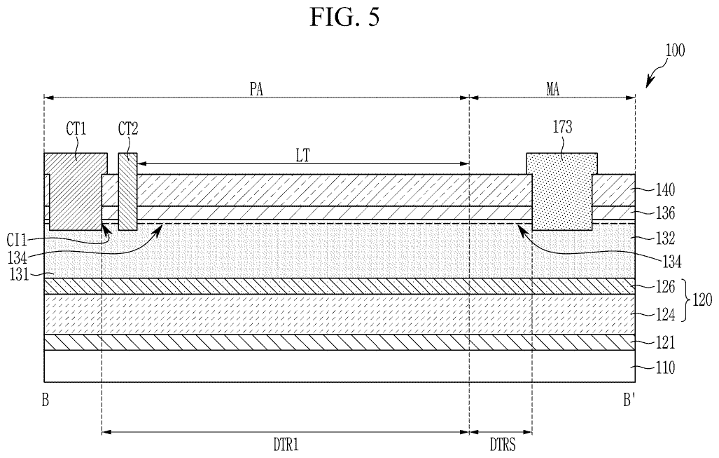

The main transistor 100 of the semiconductor device according to the embodiment may include a gate electrode G, a first electrode D, and a second electrode S. The main transistor 100 may control drain-source current between the first electrode D and the second electrode S according to a gate signal which is applied to the gate electrode G. To the first electrode D, a first power voltage VD may be supplied, and to the second electrode S, a second power voltage V_{S} may be supplied. The magnitude of the second power voltage V_{S} may be smaller than the magnitude of the first power voltage VD. For example, the second power voltage V_{S} may be a ground voltage. Here, the first electrode D may refer to the drain electrode (reference symbol “175” in FIG. 5) of the main transistor 100 according to the embodiment, and the second electrode S may refer to the source electrode (reference symbol “173” in FIG. 5) of the main transistor 100 according to the embodiment.

The temperature sensing circuit 300 according to the embodiment may include a first resistive element R1 that is connected to the source electrode 173 of the main transistor 100, and a second resistive element R2 to which a sensing power voltage V_{DD} is applied.

One end of the first resistive element R1 may be connected to one end of the main transistor 100 through a first node N1. For example, one end of the first resistive element R1 may be connected to the second electrode S of the main transistor 100 through the first node N1. Also, one end of the first resistive element R1 may be connected to a second power source having the second power voltage V_{S} through the first node N1. Accordingly, the second power voltage V_{S} may be supplied to one end of the first resistive element R1. As an example, the second power voltage V_{S} may be a ground voltage. The other end of the first resistive element R1 may be connected to the second resistive element R2 through a second node N2. In the embodiment, the first resistive element R1 may correspond to the resistance RD1 of the first drift region (reference symbol “DTR1” in FIG. 5) between the second electrode (reference symbol “173” in FIG. 5) and a sensing electrode (reference symbol “CT2” in FIG. 5). Further, the second node N2 may be a point corresponding to the sensing electrode (reference symbol “CT2” in FIG. 5). This will be described below with reference to FIG. 5.

One end of the second resistive element R2 may be connected to the first resistive element R1 through the second node N2. To the other end of the second resistive element R2, the sensing power voltage V_{DD} may be supplied. In this case, the magnitude of the sensing power voltage V_{DD} may be larger than the magnitude of the second power voltage V_{S}. In the embodiment, the second resistive element R2 may correspond to the first contact resistance (reference symbol “RC1”) of the first contact interface (reference symbol “CI1” in FIG. 5) between the power voltage electrode (reference symbol “CT1” in FIG. 5) and a channel pattern (reference symbol “131” in FIG. 5). This will be described below with reference to FIG. 5.

In the embodiment, the first resistive element R1 and the second resistive element R2 may be resistance components having predetermined resistance values. In this case, the first resistive element R1 and the second resistive element R2 may have different resistance values depending on the temperature. For example, the resistance value of the first resistive element R1 may increase as the temperature rises. In other words, the first resistive element R1 may have a positive temperature coefficient of resistance (TCR). Meanwhile, the resistance value of the second resistive element R2 may decrease as the temperature rises. In other words, the second resistive element R2 may have a negative temperature coefficient of resistance (TCR). In the embodiment, the second resistive element R2 may have a temperature coefficient of resistance (TCR) of the opposite sign to that of the first resistive element.

Accordingly, the sensing voltage V_{TS} of the second node N2 may have voltages with different magnitudes depending on the temperature. For example, when the sensing power voltage V_{DD} and the second power voltage V_{S} are supplied to both ends of the temperature sensing circuit 300, the sensing voltage V_{TS} of the second node N2 has the relationship of the following Equation 1.

$${V}_{TS} = {V}_{S} + ( {V}_{DD} - {V}_{S} ) \frac{{R}_{1}}{{R}_{1} + {R}_{2}} \qquad ( Equation 1 )$$

Here, V_{TS} represents the voltage of the second node N2, V_{S} represents the second power voltage, V_{DD} represents the sensing power voltage, R₁ represents the first resistive element value, and R₂ represents the second resistive element value.

In the embodiment, since the first resistive element R1 has a positive temperature coefficient of resistance and the second resistive element R2 has a negative temperature coefficient of resistance, the ratio between the first resistive element R1 and the second resistive element R2 may vary depending on the temperature of the semiconductor device. Therefore, the sensing voltage V_{TS} of the second node N2 may have different magnitudes depending on the temperature of the semiconductor device. For example, as the temperature of the semiconductor device rises, the magnitude of the first resistive element R1 may increase, and the magnitude of the second resistive element R2 may decrease. Accordingly, the sensing voltage V_{TS} of the second node N2 may decrease.

The temperature calculator 400 may receive a temperature signal from the temperature sensing circuit 300. The temperature calculator 400 may calculate the temperature of the semiconductor device on the basis of the temperature signal received from the temperature sensing circuit 300. For example, the temperature calculator 400 may receive a temperature signal from the second node N2 of the temperature sensing circuit 300. Here, the temperature signal may be a signal having a voltage having a different magnitude depending on the temperature of the semiconductor device; however, the present disclosure is not limited thereto. In the embodiment, the temperature signal may be the sensing voltage V_{TS} of the second node N2. Hereinafter, the case where the temperature signal is the sensing voltage V_{TS} of the second node N2 will be described.

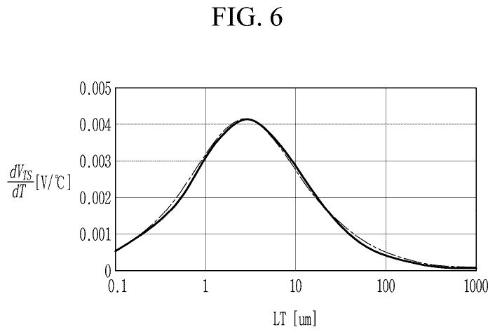

The temperature calculator 400 may calculate the temperature of the semiconductor device on the basis of the sensing voltage V_{TS} of the second node N2. For example, the temperature calculator 400 may calculate the temperature of the semiconductor device corresponding to the sensing voltage V_{TS} of the second node N2 on the basis of data on the ratio between the first resistive element R1 and the second resistive element R2 according to a pre-stored temperature. Since the sensing voltage V_{TS} of the second node N2 has a different magnitude depending on the temperature of the semiconductor device as described above, the temperature calculator 400 may calculate the ratio between the first resistive element R1 and the second resistive element R2 on the basis of the magnitude of the sensing voltage V_{TS} of the second node N2, thereby calculating the temperature of the semiconductor device. This will be described below in detail with reference to FIG. 6.

Hereinafter, the temperature sensing circuit of the semiconductor device according to the embodiment will be described with reference to FIGS. 1 and 5.

FIG. 5 is a cross-sectional view taken along line B-B′ of FIG. 1.

Referring to FIGS. 1 and 5, the temperature sensing circuit 300 that is positioned in the peripheral circuit area PA of the semiconductor device according to the embodiment may include the channel pattern 131, the barrier layer 136 that is positioned on the channel pattern 131, and the power voltage electrode CT1 and a sensing electrode CT2 that are positioned on the channel pattern 131.

The channel pattern 131 may be positioned on the substrate 110. The channel pattern 131 may be a layer that forms channels between electrodes (for example, between the sensing electrode CT2 and the source electrode 173 and/or between the sensing electrode CT2 and the power voltage electrode CT1), and inside the channel pattern 131, the two-dimensional electron gas (2DEG) 134 may be positioned. In the semiconductor device according to the embodiment, the two-dimensional electron gas 134 may occur at the interface between the channel pattern 131 and the barrier layer 136. For example, the two-dimensional electron gas 134 may occur at a portion inside the channel pattern 131 adjacent to the barrier layer 136.

In the embodiment, the channel pattern 131 may include portions each of which extends in one direction. For example, as shown in FIG. 1, the channel pattern 131 may include a portion that extends in the first direction (the X direction) from one side of the main channel layer 132 and a portion that extends in the second direction (the Y direction). However, this is only illustrative, and the extension direction of the channel pattern 131 is not limited thereto. As an example, the channel pattern 131 may extend only in one direction from one side of the main channel layer 132, or may include a plurality of bent portions. The channel pattern 131 may extend so as to have a predetermined length. Here, the extension length of the channel pattern 131 may refer to the length of the channel pattern 131 in a direction away from one side of the main channel layer 132. For example, when the channel pattern 131 includes a first portion extending in the first direction (the X direction) and a second portion extending in the second direction (the Y direction) as shown in FIG. 1, the extension length of the channel pattern 131 may be the sum of the length along the first direction (the X direction) in which the first portion extends from one side of the main channel layer 132 and the length along the second direction (the Y direction) in which the second portion extends. As another example, when the channel pattern 131 extends only in one direction (for example, the first direction (the X direction)) from one side of the main channel layer 132, the extension length of the channel pattern 131 may be substantially the same as the length of the channel pattern 131 extending in the first direction (the X direction).

In the embodiment, one end of the channel pattern 131 may be in contact with the main channel layer 132 of the main element area MA. For example, one side surface of the channel pattern 131 may be in contact with the extension portion 132a of the main channel layer 132; however, the present disclosure is not limited thereto. The channel pattern 131 may be electrically connected to the source electrode 173 through the extension portion 132a of the main channel layer 132. In this case, a first width W1 of the channel pattern 131 may be smaller than the width of the main channel layer 132. For example, the first width W1 of the channel pattern 131 may be smaller than a second width W2 of the extension portion 132a of the main channel layer 132 positioned between the channel pattern 131 and the source electrode 173. Here, the first width W1 of the channel pattern 131 may refer to the width along a direction perpendicular to the extension direction of the channel pattern 131. Further, the second width W2 of the extension portion 132a of the main channel layer 132 may refer to the width along the second direction (the Y direction). In this range, it is possible to prevent the contact resistance component between the main channel layer 132 and the source electrode 173 and the resistance component of the sub drift region DTRS of the extension portion 132a of the main channel layer 132 from affecting the temperature sensing circuit 300.

In the embodiment, the channel pattern 131 may be formed integrally with the main channel layer 132 of the main element area MA by the same process. The lower surface of the channel pattern 131 may be positioned at a level the same as a level of the lower surface of the main channel layer 132, and the upper surface of the channel pattern 131 may be positioned at a level the same as a level of the upper surface of the main channel layer 132. In other words, the lower surface of the channel pattern 131 and the lower surface of the main channel layer 132 may be positioned at the same distance from the upper surface of the substrate 110. Further, the upper surface of the channel pattern 131 and the upper surface of the main channel layer 132 may be positioned at the same distance. The channel pattern 131 may refer to a portion of the main channel layer 132 that is positioned in the peripheral circuit area PA.

In the embodiment, the channel pattern 131 may contain the same material as that of the main channel layer 132 that is positioned in the main element area MA. As an example, the channel pattern 131 may contain at least one material selected from Ill-V materials such as nitrides containing Al, Ga, In, B, or a combination thereof. The thickness of the channel pattern 131 in the third direction (the Z direction) may be substantially the same as the thickness of the main channel layer 132 in the third direction (the Z direction); however, the present disclosure is not limited thereto.

The channel pattern 131 may be positioned on the substrate 110, and between the substrate 110 and the channel pattern 131, the seed layer 121 and the buffer layer 120 may be positioned. The substrate 110, the seed layer 121, and the buffer layer 120 may be layers necessary for forming the channel pattern 131, and may be omitted in some cases. In the embodiment, the substrate 110, the seed layer 121, and the buffer layer 120 that are positioned in the peripheral circuit area PA may be formed integrally with the substrate 110, the seed layer 121, and the buffer layer 120 that are positioned in the main element area MA by the same processes, respectively.

The barrier layer 136 may be positioned on the channel pattern 131. The barrier layer 136 may be positioned directly on the channel pattern 131. However, the present disclosure is not limited thereto, and between the channel pattern 131 and the barrier layer 136, other predetermined layers may be further positioned. The region of the channel pattern 131 overlapping the barrier layer 136 may become a drift region. Specifically, as the barrier layer 136 is different from the channel pattern 131 in at least one of the polarization characteristic, the energy band gap, and the lattice constant, the 2-dimensional electron gas 134 may be induced in the channel pattern 131 having relatively low electrical polarizability by the barrier layer 136.

In the embodiment, in the peripheral circuit area PA, the channel pattern 131 may include a first drift region DTR1 between the sensing electrode CT2 and the source electrode 173. In other words, the first drift region DTR1 may refer to the region of the channel pattern 131 from one side of the channel pattern 131 in contact with the main channel layer 132 to the sensing electrode CT2. The first drift region DTR1 may refer to the region of the channel pattern 131 overlapping the barrier layer 136 between the sensing electrode CT2 and the source electrode 173. For example, the boundary between the main channel layer 132 and the channel pattern 131 may be one edge of the first drift region DTR1, and the boundary between the sensing electrode CT2 and the channel pattern 131 may be the other edge of the first drift region DTR1. In other words, the first drift region DTR1 may refer to a region in the peripheral circuit area PA between one side of the channel pattern 131 in contact with the main channel layer 132 and the sensing electrode CT2, where carriers migrate.

In the embodiment, the first drift region DTR1 may include portions each of which extends in one direction. For example, as shown in FIG. 1, the first drift region DTR1 may include a portion that extends in the first direction (the X direction) from one side of the main channel layer 132 and a portion that extends in the second direction (the Y direction). However, this is only illustrative, and the extension direction of the first drift region DTR1 is not limited thereto. As an example, the first drift region DTR1 may extend only in one direction from one side of the main channel layer 132, or may include a plurality of bent portions.

The first drift region DTR1 may have a resistance component. In other words, the first drift region DTR1 may function as the first resistive element (reference symbol “R1” in FIG. 4) having a predetermined resistance value. In other words, the region of the channel pattern 131 from one side of the channel pattern 131 to the sensing electrode CT2 may have a predetermined resistance value. In this case, the resistance (reference symbol “RD1” in FIG. 4) of the first drift region DTR1 may have a different value depending on the temperature. For example, the resistance (reference symbol “RD1” in FIG. 4) of the first drift region DTR1 may increase as the temperature rises. In other words, the resistance (reference symbol “RD1” in FIG. 4) of the first drift region DTR1 may have a positive temperature coefficient of resistance (TCR). This will be described below in detail with reference to FIG. 6 together.

The protective layer 140 may be positioned on the barrier layer 136. The lower surface of the protective layer 140 may be in contact with the barrier layer 136. In the embodiment, the protective layer 140 may be formed integrally with the protective layer 140 of the main element area MA by the same process. In other words, the protective layer 140 may be positioned on the barrier layer 136 of the main element area MA and the barrier layer 136 of the peripheral circuit area PA.

The power voltage electrode CT1 and the sensing electrode CT2 may be positioned on the channel pattern 131. The power voltage electrode CT1 and the sensing electrode CT2 may be spaced apart from each other. For example, the power voltage electrode CT1 and the sensing electrode CT2 may be spaced apart from each other in the extension direction of the channel pattern 131. In the embodiment, the power voltage electrode CT1 and the sensing electrode CT2 may be spaced apart from each other in the second direction (the Y direction); however, the present disclosure is not limited thereto. In this case, the distance between the power voltage electrode CT1 and the sensing electrode CT2 may be smaller than the distance between the sensing electrode CT2 and the source electrode 173. Further, the distance between the power voltage electrode CT1 and the sensing electrode CT2 may be smaller than the extension length of the first drift region DTR1. As an example, the distance between the power voltage electrode CT1 and the sensing electrode CT2 may be equal to or smaller than 0.5 μm. In this range, the magnitude of the resistance component between the power voltage electrode CT1 and the sensing electrode CT2 may decrease, and therefore, it is possible to prevent the sensitivity of the temperature sensing circuit 300 according to the embodiment to sense the temperature from being reduced.

Further, the power voltage electrode CT1 and the sensing electrode CT2 may be positioned apart from each other on the same plane. The lower surface of the power voltage electrode CT1 and the lower surface of the sensing electrode CT2 may be positioned substantially at the same level. In other words, the lower surface of the power voltage electrode CT1 and the lower surface of the sensing electrode CT2 may be positioned substantially at the same distance from the upper surface of the substrate 110. This may be due to the process characteristic in which the power voltage electrode CT1 and the sensing electrode CT2 are integrally formed in the same process. The lower surfaces of the power voltage electrode CT1 and the sensing electrode CT2 may be at a vertical level lower than that of an upper surface of the channel pattern 131.

Furthermore, the width of the sensing electrode CT2 in the first direction (the X direction) may be smaller than the width of the channel pattern 131 in the first direction (the X direction). Accordingly, the channel pattern 131 may be positioned on both side surfaces of the sensing electrode CT2 in the first direction (the X direction). Therefore, when carriers migrate between the first drift region DTR1 and the power voltage electrode CT1, the carriers may move to the drift region formed in the channel pattern 131 positioned on both side surfaces of the sensing electrode CT2 in the first direction (the X direction). Accordingly, in the process in which carriers migrate between the first drift region DTR1 and the power voltage electrode CT1, the contact resistance according to the contact interface between the sensing electrode CT2 and the channel pattern 131 may be minimized. Also, the width of the sensing electrode CT2 in the first direction (the X direction) may be smaller than the width of the power voltage electrode CT1 in the first direction (the X direction).

The power voltage electrode CT1 may be positioned outside the first drift region DTR1 of the channel pattern 131. The power voltage electrode CT1 may be an electrode to which the sensing power voltage (reference symbol “V_{DD}” in FIG. 4) is applied. The sensing electrode CT2 may be in contact with a side surface of the first drift region DTR1. The sensing electrode CT2 may be an electrode corresponding to the second node (reference symbol “N2” in FIG. 4) to which the temperature calculator (reference symbol “400” in FIG. 4) is connected. Accordingly, the sensing voltage V_{TS} may be transferred to the temperature calculator 400 through the sensing electrode CT2. The interface between the sensing electrode CT2 and the channel pattern 131 may be one edge of the first drift region DTR1.

In the embodiment, the power voltage electrode CT1 and the sensing electrode CT2 may be positioned inside spaces formed by recessing at least some portions of the channel pattern 131. The power voltage electrode CT1 and the sensing electrode CT2 may pass through the barrier layer 136 so as to be in contact with the side surface of the channel pattern 131. The power voltage electrode CT1 and the sensing electrode CT2 may be electrically connected to the first drift region DTR1. However, the present disclosure is not limited thereto, and the channel pattern 131 may not be recessed, and the power voltage electrode CT1 and the sensing electrode CT2 may be positioned on the upper surface of the channel pattern 131.

At least one of the power voltage electrode CT1 and the sensing electrode CT2 may cover at least some portions of the upper surface of the protective layer 140; however, the present disclosure is not limited thereto. Also, the power voltage electrode CT1 and the sensing electrode CT2 may cover at least some portions of the side surfaces of the protective layer 140. For example, the power voltage electrode CT1 and the sensing electrode CT2 may cover the side surfaces of the protective layer 140. The upper surfaces of the power voltage electrode CT1 and the sensing electrode CT2 may protrude from the upper surface of the protective layer 140.

In the embodiment, the power voltage electrode CT1 and the sensing electrode CT2 may be in ohmic contact with the channel pattern 131. In this case, the first contact interface CI1 between the power voltage electrode CT1 and the channel pattern 131 may have a resistance component. Specifically, while carriers passing through the two-dimensional electron gas 134 are transferred to the power voltage electrode CT1 through at least a portion of the channel pattern 131, i.e., the upper portion of the two-dimensional electron gas 134, the first contact interface CI1 between the power voltage electrode CT1 and the channel pattern 131 may have a predetermined resistance value. Hereinafter, for ease of explanation, the resistance of the first contact interface CI1 between the power voltage electrode CT1 and the channel pattern 131 will be referred to as the first contact resistance RC1. In the embodiment, the first contact resistance (reference symbol “RC1” in FIG. 4) may serve as the second resistive element (reference symbol “R2” in FIG. 4) having a predetermined resistance value.

In the embodiment, the first contact resistance (reference symbol “RC1” in FIG. 4) may have a different value depending on the temperature. For example, the first contact resistance (reference symbol “RC1” in FIG. 4) may decrease as the temperature rises. In other words, first contact resistance (reference symbol “RC1” in FIG. 4) may have a negative temperature coefficient of resistance (TCR). This will be described below in detail with reference to FIG. 6 together.

The power voltage electrode CT1 and the sensing electrode CT2 may contain a conductive material. The power voltage electrode CT1 and the sensing electrode CT2 may contain the same material as that of the source electrode 173 and the drain electrode 175. The power voltage electrode CT1 and the sensing electrode CT2 may be formed together with the source electrode 173 and the drain electrode 175 by the same process. For example, the power voltage electrode CT1 and the sensing electrode CT2 may contain a metal, a metal alloy, a conductive metal nitride, a metal silicide, a doped semiconductor material, a conductive metal oxide, a conductive metal oxynitride, or the like. For example, the power voltage electrode CT1 and the sensing electrode CT2 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAI), titanium aluminum carbo-nitride (TiAlC—N), titanium aluminum carbide (TiAlC), titanium carbide (TiC), tantalum carbo-nitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The power voltage electrode CT1 and the sensing electrode CT2 may consist of a single layer or multiple layers. The power voltage electrode CT1 and the sensing electrode CT2 may be in ohmic contact with the channel pattern 131. The region in the channel pattern 131 which is in contact with the power voltage electrode CT1 and the sensing electrode CT2 may be doped at a relatively higher concentration as compared to the other region; however, the present disclosure is not limited thereto.

In the embodiment, the temperature sensing circuit 300 may be separated from the main transistor 100 by the separation structure 160. In other words, between the temperature sensing circuit 300 and the main transistor 100, the separation structure may be positioned. The separation structure 160 may pass through the barrier layer 136 and recess at least a portion of the channel pattern 131; however, the present disclosure is not limited thereto. Therefore, the first drift region DTR1 of the temperature sensing circuit 300 may be electrically insulated from the main transistor 100. However, the present disclosure is not limited thereto, and as another example, the separation structure 160 may pass through the barrier layer 136 and the channel pattern 131. As a further example, the temperature sensing circuit 300 and the main transistor 100 may be separated by a trench passing through at least a portion of at least one of the channel pattern 131 and the main channel layer 132.

Hereinafter, the temperature sensing circuit of the semiconductor device according to the embodiment will be described with reference to FIG. 6 together.

FIG. 6 is a graph illustrating the degree of sensitivity of the temperature sensing circuit of the semiconductor device according to the embodiment. FIG. 6 is a graph illustrating the degree of sensitivity of the temperature sensing circuit 300 according to the extension length LT of the first drift region DTR1.

As described above, the resistance RD1 of the first drift region DTR1 may have a positive temperature coefficient of resistance (TCR), and the first contact resistance RC1 may have a negative temperature coefficient of resistance (TCR).

Specifically, the resistance RD1 of the first drift region DTR1 according to the temperature has the relationship of the following Equation 2.

$$RDU = {A}_{2} T + {K}_{2} [ Ω / um ] \qquad ( Equation 2 )$$

Here, RDU represents the unit resistance (Ω) of the first drift region DTR1 per unit length (μm), and T represents the temperature (° C.), and A₂ represents the temperature coefficient of resistance (TCR) of the first drift region DTR1. Further, K₂ is a constant. The unit resistance value RDU of the first drift region DTR1 may refer to the resistance value of the resistance RD1 of the first drift region DTR1 per unit length. In this case, the temperature coefficient of resistance of the first drift region DTR1 may have a positive value. For example, the temperature coefficient of resistance of the first drift region DTR1 may be about 5 (Ω/μm° C.) to about 15 (Ω/μm° C.). Accordingly, the resistance RD1 of the first drift region DTR1 may increase as the temperature rises.

The resistance RD1 of the first drift region DTR1 may be calculated by multiplying the unit resistance value RDU of the first drift region DTR1 by the extension length LT of the first drift region DTR1. As an example, when the extension length LT of the first drift region DTR1 is 1 μm to 10 μm, the resistance RD1 of the first drift region DTR1 may be one time to ten times the unit resistance value RDU of the first drift region DTR1. In other words, the resistance of the first drift region DTR1 may be expressed as the following Equation 3.

$$RD = ( LT ) RDU = ( LT ) {A}_{2} T + ( LT ) {K}_{2} [ Ω / um ] \qquad ( Equation 3 )$$

Here, RD may represent the resistance (Ω) of the first drift region DTR1, and LT may represent the extension length (μm) of the first drift region DTR1. The extension length LT of the first drift region DTR1 may refer to the length in a direction away from one side of the main channel layer 132. For example, when the first drift region DTR1 includes the first portion extending in the first direction (the X direction) and the second portion extending in the second direction (the Y direction) as shown in FIGS. 1 and 5, the extension length LT of the first drift region DTR1 may be the sum of the extension length of the first portion in the first direction (the X direction) from one side of the main channel layer 132 and the extension length of the second portion in the second direction (the Y direction). As another example, when the first drift region DTR1 extends only in one direction (for example, the first direction (the X direction)) from one side of the main channel layer 132, the extension length LT of the first drift region DTR1 may be substantially the same as the extension length of the first drift region DTR1 in the first direction (the X direction).

Meanwhile, first, the first contact resistance RC1 according to the temperature has the relationship of the following Equation 4.

$$RC = {A}_{1} T + {K}_{1} [ Ω / um ] \qquad ( Equation 4 )$$

Here, RC represents the resistance value (Ω) of the first contact resistance RC1, and T represents the temperature (° C.), and A₁ represents the temperature coefficient of resistance (TCR) of the first contact resistance RC1. Further, Ki is a constant. In this case, the temperature coefficient of resistance (TCR) of the first contact resistance RC1 may have a negative value. For example, the temperature coefficient of resistance (TCR) of the first contact resistance RC1 may be about −20 (Ω/° C.) to about −10 (Ω/° C.). Therefore, the first contact resistance RC1 may decrease as the temperature rises. In the embodiment, the temperature coefficient of resistance (TCR) of the first contact resistance RC1 may be larger than the temperature coefficient of resistance of the first drift region DTR1; however, the present disclosure is not limited thereto.

In summary, since the resistance RD1 of the first drift region DTR1 has a positive temperature coefficient of resistance and the first contact resistance RC1 has a negative temperature coefficient of resistance, the ratio between the resistance RD1 of the first drift region DTR1 and the first contact resistance RC1 may have a different value depending on the temperature of the semiconductor device. Therefore, the sensing voltage V_{TS} of the sensing electrode CT2 may have a different magnitude depending on the temperature of the semiconductor device.

Further, the amount of change in the resistance RD1 of the first drift region DTR1 according to a change in the temperature may depend on the temperature coefficient of resistance of the first drift region DTR1 and the extension length LT of the first drift region DTR1. Meanwhile, the amount of change in the first contact resistance RC1 according to a change in the temperature may depend on the temperature coefficient of resistance of the first contact resistance RC1.

In this case, the temperature sensing circuit 300 may have a different degree of sensitivity depending on the extension length LT of the first drift region DTR1. Here, the degree of sensitivity of the temperature sensing circuit 300 may be defined as an amount of change in the sensing voltage V_{TS} according to an amount of change in the temperature. In other words, when the degree of sensitivity of the temperature sensing circuit 300 is high, the amount of change in the sensing voltage V_{TS} with respect to an amount of unit temperature change may be relatively large, and therefore, it is possible to relatively accurately calculate the temperature of the semiconductor device. For example, as shown in FIG. 6, the extension length LT of the first drift region DTR1 according to the embodiment may be 1 μm to 10 μm. Preferably, the extension length LT of the first drift region DTR1 may be 2 μm to 4 μm. In this case, the ratio of the resistance RD1 of the first drift region DTR1 to the first contact resistance RC1 may be equal to or smaller than 6. In this range, the degree of sensitivity of the temperature sensing circuit 300 may relatively increase, and accordingly, the temperature of the semiconductor device may be calculated relatively accurately.

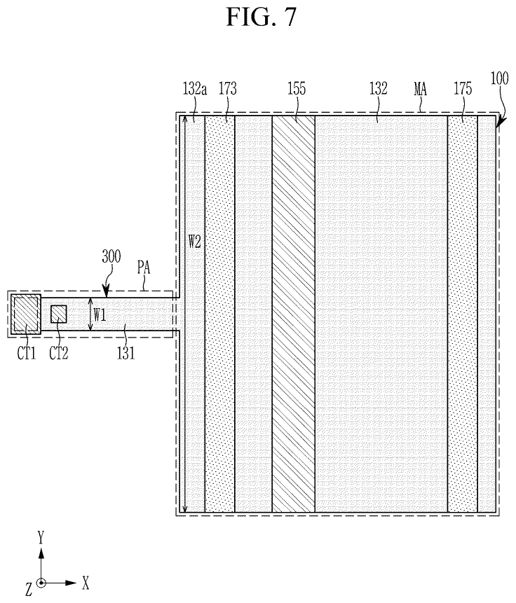

Hereinafter, semiconductor devices according to some embodiments will be described with reference to FIGS. 7 to 9.

FIGS. 7 to 9 are plan views illustrating semiconductor devices according to some embodiments. In FIGS. 7 to 9, temperature calculators 400 that are connected to sensing electrodes CT2 of temperature sensing circuits 300 of the semiconductor devices according to some embodiments are omitted. Of course, the temperature calculators 400 in the embodiments of FIGS. 7 to 9 may be connected to the sensing electrodes CT2, similar to the temperature calculator 400 of the embodiment of FIGS. 1 to 6, and may receive the sensing voltage V_{TS} from the sensing electrodes CT2 and calculate the temperatures of the semiconductor devices.

FIGS. 7 to 9 illustrate various modifications of the semiconductor device according to the embodiment shown in FIGS. 1 to 6. Since the embodiment shown in FIGS. 7 to 9 have many portions identical to those of the embodiment shown in FIGS. 1 to 6, a description thereof will not be made and the differences will be mainly described. Also, constituent elements identical to those of the above embodiment are denoted by the same reference symbols.

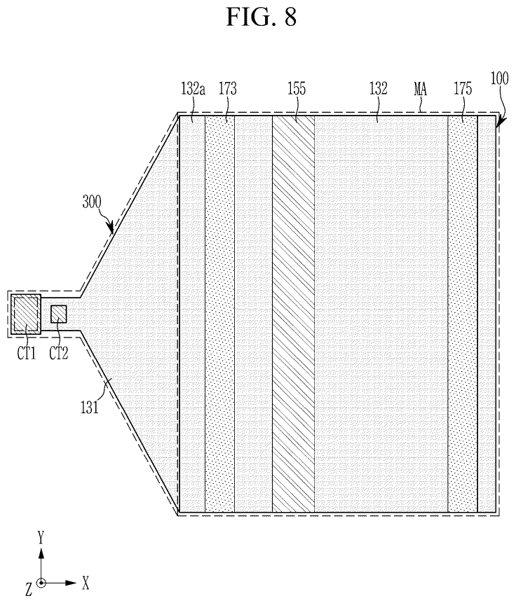

Referring to FIGS. 7 and 8, in some embodiments, the channel pattern 131 of the temperature sensing circuit 300 that is positioned in the peripheral circuit area PA may have various shapes.

For example, as shown in FIG. 7, a peripheral circuit area PA of a semiconductor device according to some embodiments may extend in the first direction (the X direction) from one side of a main element area MA. In some embodiments, a channel pattern 131 may extend in the first direction (the X direction) from one side of the main element area MA. In this case, in some embodiments, the extension length of the channel pattern 131 may refer to the extension length of the channel pattern 131 in the first direction (the X direction) from one side of the main channel layer 132. As an example, the extension length of the channel pattern 131 may be 1 μm to 10 μm, and preferably, 2 μm to 4 μm. Further, a first width W1 of the channel pattern 131 may refer to the width of the channel pattern 131 in the second direction (the Y direction). In some embodiments, the first width W1 of the channel pattern 131 in the second direction (the Y direction) may be smaller than the second width W2 of the main channel layer 132 in the second direction (the Y direction). In FIG. 7, it is shown that the channel pattern 131 extends in the first direction (the X direction); however, the present disclosure is not limited thereto, and the extension direction of the channel pattern 131 may be variously changed. As another example, as shown in FIG. 8, the width of the channel pattern 131 in the second direction (the Y direction) may decrease in a direction away from one side of the main channel layer 132.

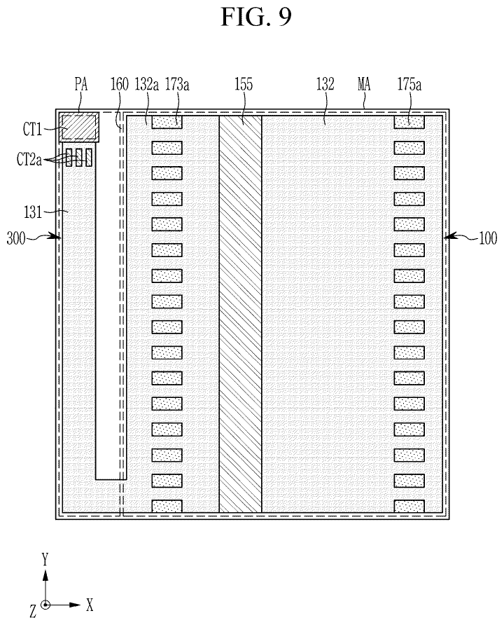

Referring to FIG. 9, a main transistor 100 of a semiconductor device according to some embodiments may include a plurality of source electrodes 173a and a plurality of drain electrodes 175a. For example, the plurality of source electrodes 173a and the plurality of drain electrodes 175a may be arranged along the second direction (the Y direction). For example, the plurality of source electrodes 173a may be aligned with one another in the second direction (the Y direction), and the plurality of drain electrodes 175a may be aligned with one another in the second direction (the Y direction). The plurality of source electrodes 173a and the plurality of drain electrodes 175a may be positioned inside a plurality of spaces formed by recessing at least some portions of a main channel layer 132 repeatedly along the second direction (the Y direction). The main channel layer 132 may be positioned between the plurality of source electrodes 173a adjacent in the second direction (the Y direction) and between the plurality of drain electrodes 175a adjacent in the second direction (the Y direction); however, the present disclosure is not limited thereto. For example, the source electrodes 173a and the drain electrodes 175a may be positioned inside the plurality of spaces formed by repeatedly recessing at least some portions of the main channel layer 132 along the second direction (the Y direction) and on the main channel layer 132 between the plurality of spaces. In this case, the plurality of source electrodes 173a and the plurality of drain electrodes 175a may be integrally formed.

In some embodiments, a plurality of sensing electrodes CT2a may be provided. For example, the plurality of sensing electrodes CT2a may be arranged along the first direction (the X direction). The width of each of the plurality of sensing electrodes CT2a in the first direction (the X direction) may be smaller than the width of the channel pattern 131 in the first direction (the X direction). Between the plurality of sensing electrodes CT2a adjacent in the first direction (the X direction), the channel pattern 131 may be positioned. Accordingly, when carriers migrate between the first drift region DTR1 and the power voltage electrode CT1, the carriers may migrate to the drift region formed in the channel pattern 131 positioned between the plurality of sensing electrodes CT2a adjacent in the first direction (the X direction). Therefore, in the process in which carriers migrate between the first drift region DTR1 and the power voltage electrode CT1, the contact resistance according to the contact interfaces between the sensing electrodes CT2a and the channel pattern 131 may be minimized.

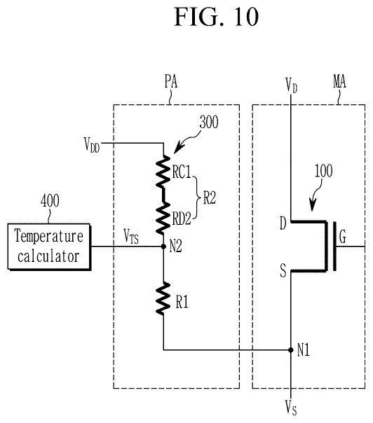

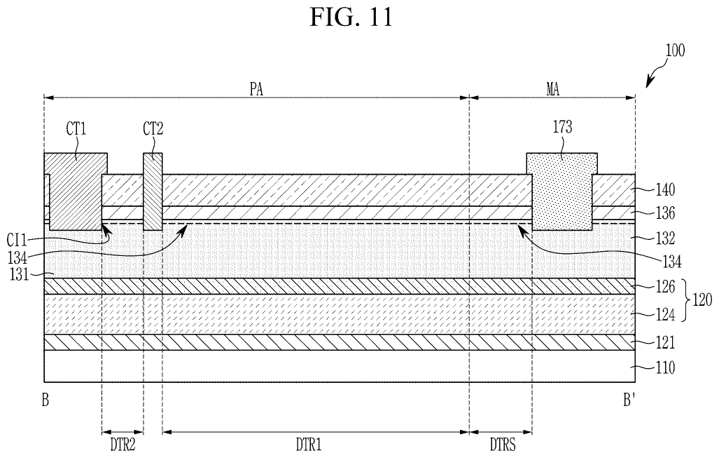

Hereinafter, an electronic system including a semiconductor device according to some embodiments will be described with reference to FIGS. 10 and 11.

FIG. 10 is a circuit diagram illustrating an electronic system including a semiconductor device according to some embodiments. FIG. 11 is a cross-sectional view that illustrates a semiconductor device according to some embodiments and corresponds to an area taken along line B-B′ of FIG. 1.

FIGS. 10 and 11 illustrate various modifications of the semiconductor device according to the embodiment shown in FIGS. 1 to 6. Since the embodiments shown in FIGS. 10 and 11 have many portions identical to those of the embodiment shown in FIGS. 1 to 6, a description thereof will not be repeated and the differences will be mainly described. Also, constituent elements identical to those of the above embodiment are denoted by the same reference symbols.

Referring to FIG. 10, the second resistive element R2 of the temperature sensing circuit 300 of the semiconductor device according to some embodiments may further include the resistance RD2 of a second drift region DTR2. In other words, the second resistive element R2 may include the resistance RD2 of the second drift region DTR2 and the first contact resistance RC1. One end of the resistance RD2 of the second drift region DTR2 may be connected to the first resistive element R1 through the second node N2. The other end of the resistance RD2 of the second drift region DTR2 may be connected to the first contact resistance RC1.

Referring to FIG. 11 together, in the peripheral circuit area PA, the channel pattern 131 may include the second drift region DTR2 between the sensing electrode CT2 and the power voltage electrode CT1. In other words, the second drift region DTR2 may refer to the region of the channel pattern 131 overlapping the barrier layer 136 between the sensing electrode CT2 and the power voltage electrode CT1. For example, the boundary between the sensing electrode CT2 and the channel pattern 131 may be one edge of the second drift region DTR2, and the boundary between the power voltage electrode CT1 and the channel pattern 131 may be the other edge of the second drift region DTR2. In the embodiment, the second drift region DTR2 may extend in one direction; however, the present disclosure is not limited thereto.

In the embodiment, the second drift region DTR2 may have a resistance component. In other words, the second drift region DTR2 may serve as a portion of the second resistive element R2 having a predetermined resistance value. In this case, the resistance RD2 of the second drift region DTR2 may have a different value depending on the temperature. For example, the resistance RD2 of the second drift region DTR2 may increase as the temperature rises. In other words, the resistance RD2 of the second drift region DTR2 may have a positive temperature coefficient of resistance (TCR).

Accordingly, the temperature calculator 400 according to some embodiments may calculate the temperature of the semiconductor device on the basis of the sensing voltage V_{TS} of the sensing electrode CT2. For example, the temperature calculator 400 may calculate the temperature of the semiconductor device corresponding to the sensing voltage V_{TS} of the sensing electrode CT2 on the basis of data on the ratio between the first resistive element R1 and the second resistive element R2 according to a pre-stored temperature. In other words, the temperature calculator 400 may calculate the temperature of the semiconductor device on the basis of the ratio between the sum of the value of the resistance RD2 of the second drift region DTR2 and the value of the first contact resistance RC1 and the value of the resistance RD1 of the first drift region DTR1.

In some embodiments, it has been designated that the first resistive element R1 consists of only the resistance RD1 of the first drift region DTR1; however, the present disclosure is not limited thereto. For example, the first resistive element R1 may include the resistance RD1 of the first drift region DTR1 and the resistance of the sub drift region DTRS. In this case, the temperature calculator 400 may calculate the temperature of the semiconductor device on the basis of the ratio between the sum of the value of the resistance RD2 of the second drift region DTR2 and the value of the first contact resistance RC1 and the sum of the value of the resistance RD1 of the first drift region DTR1 and the resistance value of the sub drift region DTRS. As another example, the first resistive element R1 may further include the contact resistance at the contact interface between the source electrode 173 and the main channel layer 132. In this case, the temperature calculator 400 may calculate the temperature of the semiconductor device on the basis of the ratio between the sum of the value of the resistance RD2 of the second drift region DTR2 and the value of the first contact resistance RC1 and the sum of the value of the resistance RD1 of the first drift region DTR1, the resistance value of the sub drift region DTRS, and the contact resistance value at the contact interface between the source electrode 173 and the main channel layer 132.

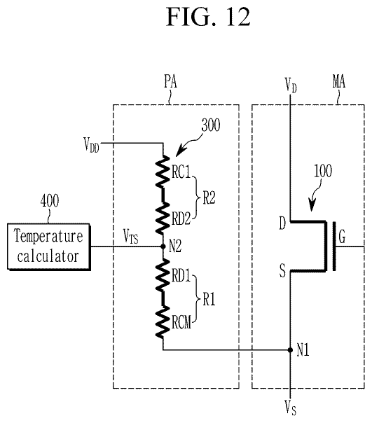

Hereinafter, an electronic system including a semiconductor device according to some embodiments will be described with reference to FIGS. 12 to 14.

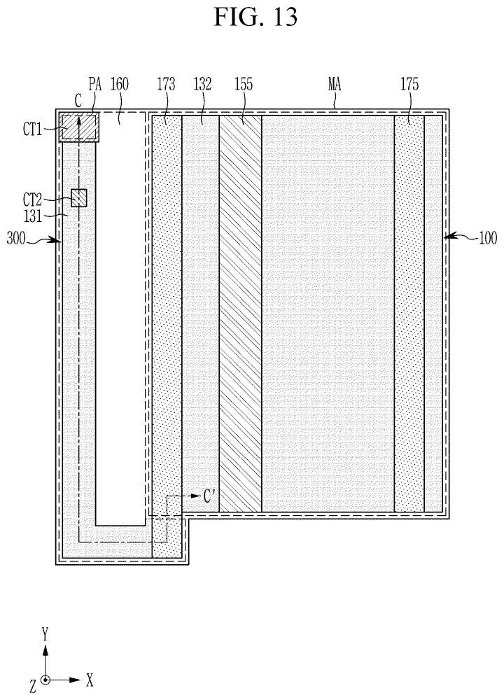

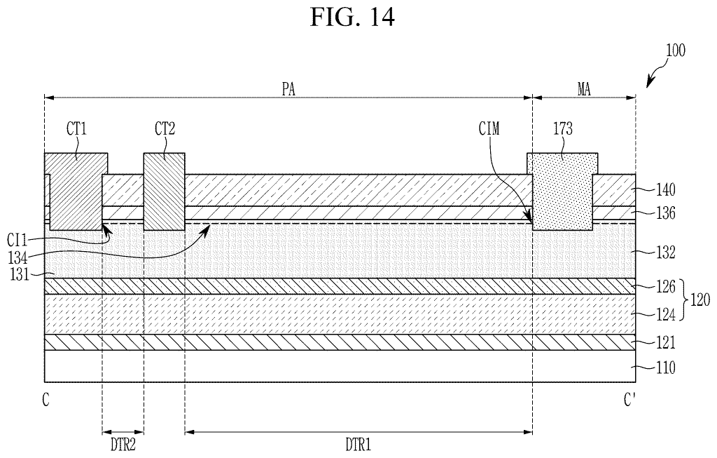

FIG. 12 is a circuit diagram illustrating an electronic system including a semiconductor device according to some embodiments. FIG. 13 is a plan view illustrating the semiconductor device according to some embodiments. FIG. 14 is a cross-sectional view taken along line C-C′ of FIG. 13. For ease of explanation, in FIG. 13, a temperature calculator 400 that is connected to a sensing electrode CT2 of a temperature sensing circuit 300 of the semiconductor device according to some embodiments is omitted. Of course, the temperature calculator 400 in the embodiment of FIG. 13 may be connected to the sensing electrode CT2, similar to the temperature calculator 400 of the embodiment of FIGS. 10 and 11, and may receive the sensing voltage V_{TS} from the sensing electrode CT2 and calculate the temperature of the semiconductor device.

FIGS. 12 to 14 illustrate various modifications of the semiconductor device according to the embodiment shown in FIGS. 10 and 11. Since the embodiment shown in FIGS. 12 to 14 have many portions identical to those of the embodiment shown in FIGS. 10 and 11, a description thereof will not be made and the differences will be mainly described. Also, constituent elements identical to those of the above embodiment are denoted by the same reference symbols.

Referring to FIG. 12, the first resistive element R1 of a semiconductor device according to some embodiments may further include main contact resistance RCM. In other words, the first resistive element R1 may include the main contact resistance RCM and the resistance RD1 of the first drift region DTR1. One end of the main contact resistance RCM may be connected to the main transistor 100 through the first node N1 and receive the second power voltage V_{S}. The other end of the main contact resistance RCM may be connected to the resistance of the first drift region DTR1.

In some embodiments, the temperature calculator 400 may calculate the temperature of the semiconductor device on the basis of the sensing voltage V_{TS} of the sensing electrode CT2. For example, the temperature calculator 400 may calculate the temperature of the semiconductor device corresponding to the sensing voltage V_{TS} of the sensing electrode CT2 on the basis of data on the ratio between the first resistive element R1 and the second resistive element R2 according to a pre-stored temperature. In other words, in some embodiments, the temperature calculator 400 may calculate the temperature of the semiconductor device on the basis of the ratio between the sum of the value of the resistance RD2 of the second drift region DTR2 and the value of the first contact resistance RC1 and the sum of the value of the resistance RD1 of the first drift region DTR1 and the value of the main contact resistance RCM.

Referring to FIGS. 13 and 14 together, a channel pattern 131 according to some embodiments may be in contact with the source electrode 173 of the main transistor 100 positioned in the main element area MA. For example, the channel pattern 131 may be in contact with a side surface of the source electrode 173. In some embodiments, no extensions may be provided between the source electrode 173 and the channel pattern 131.

In this case, a main contact interface CIM between the source electrode 173 and the channel pattern 131 may have a resistance component. The main contact interface CIM between the source electrode 173 and the channel pattern 131 may have a predetermined resistance value. Hereinafter, for ease of explanation, the resistance of the main contact interface CIM between the source electrode 173 and the channel pattern 131 will be defined as main contact resistance RCM. In an embodiment, the main contact resistance RCM may serve as a portion of the first resistive element R1 having a predetermined resistance value.

In the embodiment, the main contact resistance RCM may have a different value depending on the temperature. For example, the main contact resistance RCM may decrease as the temperature rises. In other words, the main contact resistance RCM may have a negative temperature coefficient of resistance (TCR).

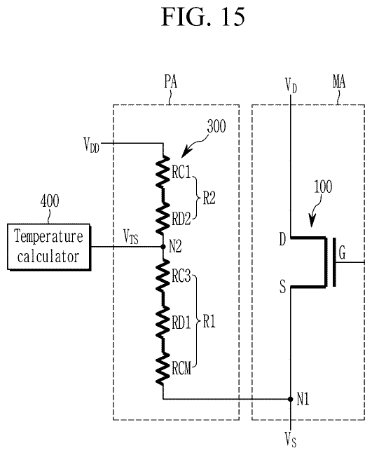

Hereinafter, an electronic system including a semiconductor device according to some embodiments will be described with reference to FIGS. 15 to 17.

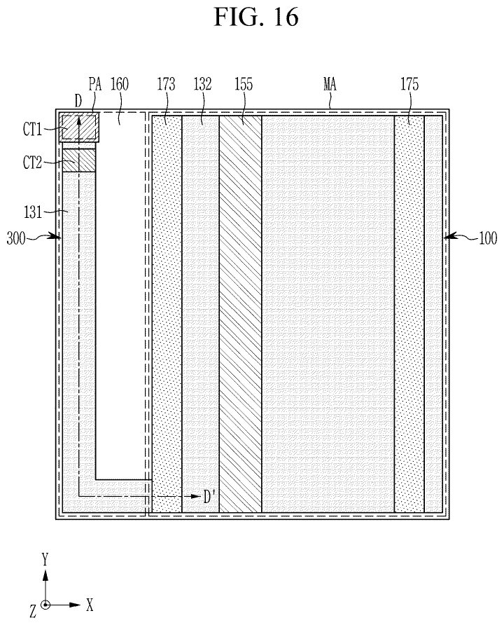

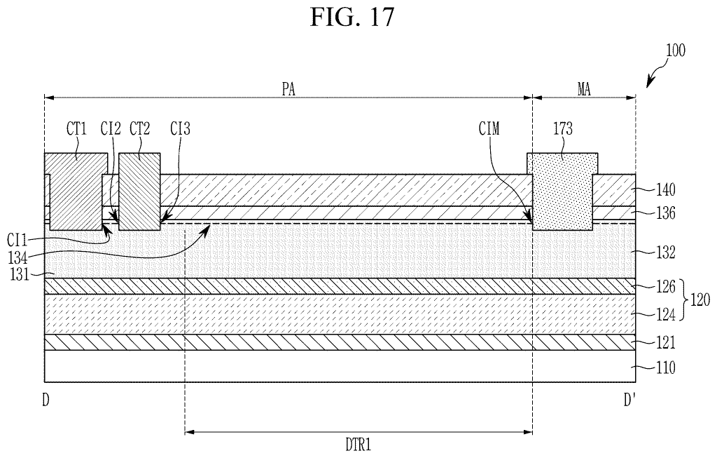

FIG. 15 is a circuit diagram illustrating an electronic system including a semiconductor device according to some embodiments. FIG. 16 is a plan view illustrating the semiconductor device according to some embodiments. FIG. 17 is a cross-sectional view taken along line D-D′ of FIG. 16. For ease of explanation, in FIG. 16, a temperature calculator 400 that is connected to a sensing electrode CT2 of a temperature sensing circuit 300 of the semiconductor device according to some embodiments is omitted. Of course, the temperature calculator 400 in the embodiment of FIG. 16 may be connected to the sensing electrode CT2, similar to the temperature calculator 400 of the embodiment of FIGS. 12 to 14, and may receive the sensing voltage V_{TS} from the sensing electrode CT2 and calculate the temperature of the semiconductor device.

FIGS. 15 to 17 illustrate various modifications of the semiconductor device according to the embodiment shown in FIGS. 12 to 14. Since the embodiment shown in FIGS. 15 to 17 has many portions identical to those of the embodiment shown in FIGS. 12 to 14, descriptions thereof will not be repeated and the differences will be mainly described. Also, constituent elements identical to those of the above embodiment are denoted by the same reference symbols.

In the embodiment of FIGS. 12 to 14, the first resistive element R1 may include the first contact resistance RC1 and the resistance RD2 of the second drift region DTR2, and the second resistive element R2 may include the resistance RD1 of the first drift region DTR1 and the main contact resistance RCM.

Referring to FIG. 15, the first resistive element R1 of the temperature sensing circuit 300 according to some embodiments may include the first contact resistance RC1 and a second contact resistance RC2, and the second resistive element R2 may include the resistance RD1 of the first drift region DTR1, the main contact resistance RCM, and a third contact resistance RC3.

The second contact resistance RC2 may connect the first contact resistance RC1 and the second node N2. One end of the second contact resistance RC2 may be connected to the first resistive element R1 through the second node N2, and the sensing power voltage V_{DD} may be supplied to the other end of the second contact resistance RC2 through the first contact resistance RC1. In some embodiments, the second contact resistance RC2 may be resistance caused by the interface between the sensing electrode CT2 and the channel pattern 131.

The third contact resistance RC3 may connect the second contact resistance RC2 and the resistance of the first drift region DTR1. One end of the third contact resistance RC3 may be connected to the second resistive element R2 through the second node N2, and the second power voltage V_{S} may be supplied to the other end of the third contact resistance RC3 through the first node N1. In some embodiments, the third contact resistance RC3 may be resistance caused by the interface between the sensing electrode CT2 and the channel pattern 131.

In some embodiments, the temperature calculator 400 may calculate the temperature of the semiconductor device on the basis of the sensing voltage V_{TS} of the sensing electrode CT2. For example, the temperature calculator 400 may calculate the temperature of the semiconductor device corresponding to the sensing voltage V_{TS} of the sensing electrode CT2 on the basis of data on the ratio between the first resistive element R1 and the second resistive element R2 according to a pre-stored temperature. In other words, in some embodiments, the temperature calculator 400 may calculate the temperature of the semiconductor device on the basis of the ratio between the sum of the value of the first contact resistance RC1 and the value of the second contact resistance RC2 and the sum of the value of the resistance RD1 of the first drift region DTR1, the value of the main contact resistance RCM, and the value of the third contact resistance RC3.

Referring to FIGS. 16 and 17 together, in some embodiments, the width of the sensing electrode CT2 in the first direction (the X direction) may be substantially the same as the width of the channel pattern 131 in the first direction (the X direction). Accordingly, at the point where the sensing electrode CT2 is positioned, the two-dimensional electron gas may not be formed. Therefore, when carriers migrate from the power voltage electrode CT1 to the source electrode 173 of the main transistor 100, the carriers may migrate through the sensing electrode CT2.

At this time, the interface between the sensing electrode CT2 and the channel pattern 131 may have a resistance component. For example, the second contact interface CI2 between one side of the sensing electrode CT2 in the second direction (the Y direction) and the channel pattern 131 and the third contact interface CI3 between the other side of the sensing electrode CT2 in the second direction (the Y direction) and the channel pattern 131 may have predetermined resistance values. The resistance of the second contact interface CI2 may be defined as the second contact resistance RC2, and the resistance of the third contact interface may be defined as the third contact resistance RC3.

In some embodiments, the second contact resistance RC2 and the third contact resistance RC3 may have different values depending on the temperature. For example, the second contact resistance RC2 and the third contact resistance RC3 may decrease as the temperature rises. In other words, the second contact resistance RC2 and the third contact resistance RC3 may have negative temperature coefficients of resistance (TCRs). The magnitude of the second contact resistance RC2 and the magnitude of the third contact resistance RC3 may be substantially the same; however, the present disclosure is not limited thereto.

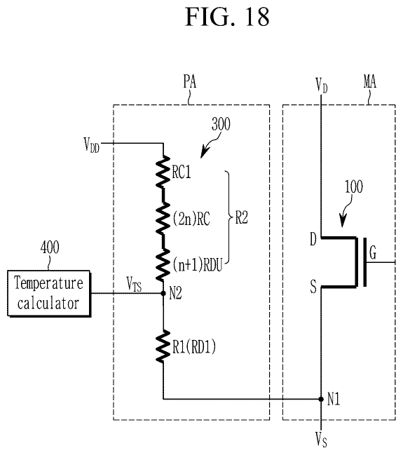

Hereinafter, an electronic system including a semiconductor device according to some embodiments will be described with reference to FIGS. 18 to 21.

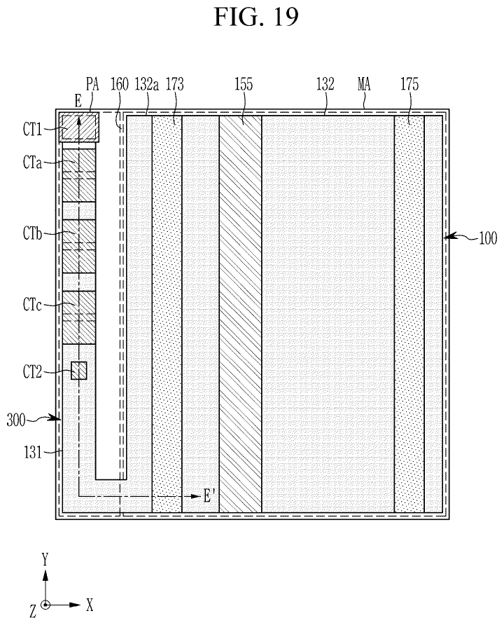

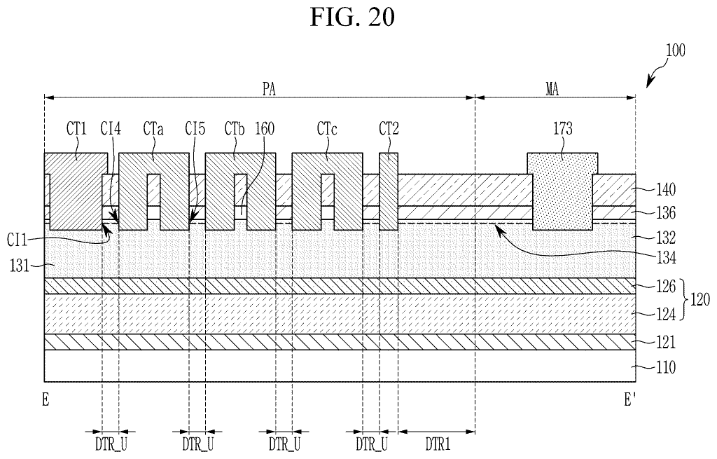

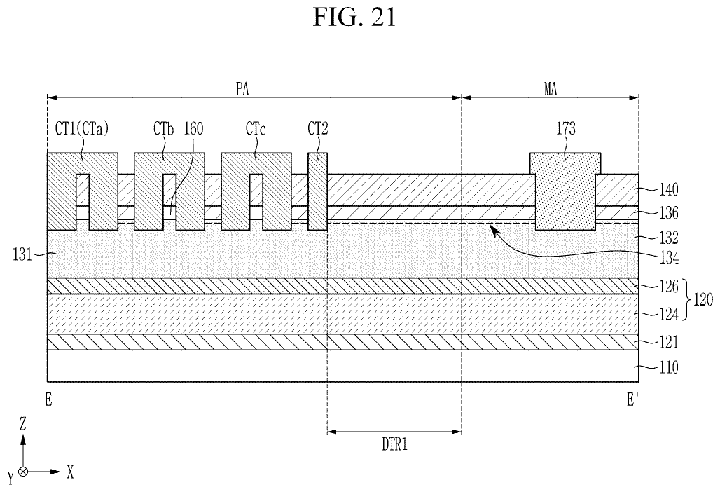

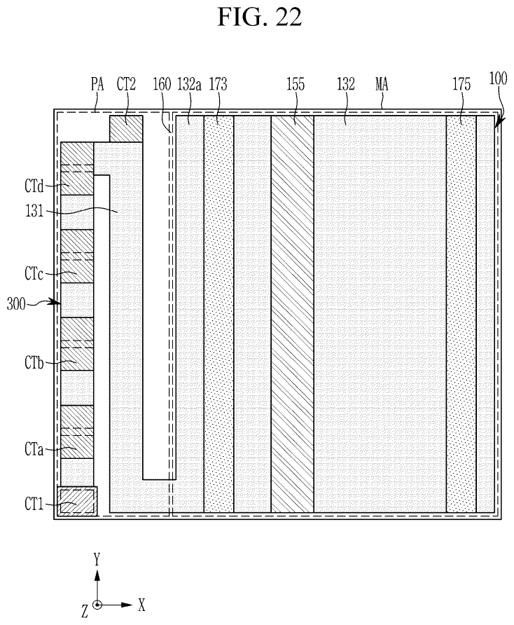

FIG. 18 is a circuit diagram illustrating an electronic system including a semiconductor device according to some embodiments. FIG. 19 is a plan view illustrating the semiconductor device according to some embodiments. FIGS. 20 and 21 are cross-sectional views taken along line E-E′ of FIG. 19. FIG. 22 is a plan view illustrating the semiconductor device according to some embodiments. For ease of explanation, in FIG. 19, a temperature calculator 400 that is connected to a sensing electrode CT2 of a temperature sensing circuit 300 of the semiconductor device according to some embodiments is omitted. Of course, the temperature calculators 400 in the embodiment of FIG. 19 may be connected to the sensing electrodes CT2, similar to the temperature calculator 400 of the embodiment of FIGS. 1 to 6, and may receive the sensing voltage V_{TS} from the sensing electrodes CT2 and calculate the temperatures of the semiconductor devices.

FIGS. 18 to 22 illustrate various modifications of the semiconductor device according to the embodiment shown in FIGS. 1 to 6. Since the embodiment shown in FIGS. 18 to 22 has many portions identical to those of the embodiment shown in FIGS. 1 to 6, descriptions thereof will not be repeated and the differences will be mainly described. Also, constituent elements identical to those of the above embodiment are denoted by the same reference symbols.

First, referring to FIG. 18, the second resistive element R2 of the temperature sensing circuit 300 according to some embodiments may include a plurality of resistance units. The plurality of resistance units may include a plurality of unit contact resistance (2n)RC and the resistance (n+1)RDU of a plurality of unit drift regions CTR_U.

The plurality of unit contact resistance (2n)RC and the resistance (n+1)RDU of the plurality of unit drift regions CTR_U may connect the second node N2 and the first contact resistance RC1. To one end of the plurality of resistance units, the sensing voltage V_{TS} may be supplied through the first contact resistance RC1. The other end of the plurality of resistance units may be connected to the first resistive element R1 through the second node N2.

In some embodiments, the plurality of unit contact resistance (2n)RC may have negative temperature coefficients of resistance (TCRs), and the resistance (n+1)RDU of the plurality of unit drift regions CTR_U may have positive temperature coefficients of resistance (TCRs).

In some embodiments, the temperature calculator 400 may calculate the temperature of the semiconductor device on the basis of the sensing voltage V_{TS} of the sensing electrode CT2. For example, the temperature calculator 400 may calculate the temperature of the semiconductor device corresponding to the sensing voltage V_{TS} of the sensing electrode CT2 on the basis of data on the ratio between the first resistive element R1 and the second resistive element R2 according to a pre-stored temperature. In other words, in some embodiments, the temperature calculator 400 may calculate the temperature of the semiconductor device based on the ratio between the sum of the value of the first contact resistance RC1, the values of the plurality of unit contact resistance (2n)RC, and the values of the resistance (n+1)RDU of the plurality of unit drift regions CTR_U and the value of the resistance RD1 of the first drift region DTR1.

Subsequently, referring to FIGS. 19 to 22 together, the peripheral circuit area PA of the semiconductor device according to some embodiments may include a plurality of contact units CTa to CTc. Here, the plurality of contact units CTa to CTc may correspond to the plurality of resistance units, respectively.

In some embodiments, the plurality of contact units CTa to CTc may be positioned on the channel pattern 131. The plurality of contact units CTa to CTc may be spaced apart from each other. For example, the plurality of contact units CTa to CTc may be spaced apart from each other along the extension direction of the channel pattern 131. In some embodiments, the first contact unit CTa, the second contact unit CTb, and the third contact unit CTc may be spaced apart from each other in the second direction (the Y direction); however, the present disclosure is not limited thereto.

The plurality of contact units CTa to CTc may be positioned apart from each other on the same plane. The lower surfaces of the plurality of contact units CTa to CTc may be substantially at the same level. In other words, the lower surfaces of the plurality of contact units CTa to CTc may be positioned substantially at the same distance from the upper surface of the substrate 110. The lower surfaces of the plurality of contact units CTa to CTc may be positioned at a ertical level lower than that of the upper surface of the channel pattern 131. The lower surfaces of the plurality of contact units CTa to CTc may be positioned substantially at a level with the lower surface of the sensing electrode CT2 and the lower surface of the power voltage electrode CT1. This may be due to the process characteristic in which the plurality of contact units CTa to CTc is integrally formed together with the power voltage electrode CT1 and the sensing electrode CT2 in the same process.

In some embodiments, the plurality of contact units CTa to CTc may be positioned between the power voltage electrode CT1 and the sensing electrode CT2. For example, as shown in FIG. 20, three contact units CTa to CTc may be positioned between the power voltage electrode CT1 and the sensing electrode CT2. In some embodiments, any one of the plurality of contact units CTa to CTc may serve as the power voltage electrode CT1. For example, as shown in FIG. 21, the first contact unit CTa may serve as the power voltage electrode CT1. In other words, the sensing power voltage (reference symbol “V_{DD}” in FIG. 18) may be supplied through the first contact unit CTa. Although not shown in the drawings, any one of the plurality of contact units CTa to CTc may serve as the sensing electrode CT2.

In some embodiments, the plurality of contact units CTa to CTc may be positioned inside spaces formed by recessing at least some portions of the channel pattern 131. The plurality of contact units CTa to CTc may pass through the barrier layer 136 so as to be in contact with the side surface of the channel pattern 131. Side surfaces of the plurality of contact units CTa to CTc may contact the barrier layer 136. The plurality of contact units CTa to CTc may be electrically connected to the first drift region DTR1. However, the present disclosure is not limited thereto, and the channel pattern 131 may not be recessed, and the plurality of contact units CTa to CTc may be positioned on the upper surface of the channel pattern 131.

In the embodiment, the plurality of contact units CTa to CTc may be in ohmic contact with the channel pattern 131. In this case, the interfaces between the plurality of contact units CTa to CTc and the channel pattern 131 may have resistance components. For example, a fourth contact interface CI4 between one side of the first contact unit CTa in the second direction (the Y direction) and the channel pattern 131 and a fifth contact interface CI5 between the other side of the first contact unit CTa in the second direction (the Y direction) and the channel pattern 131 may have resistance components. Further, the contact interfaces on opposite sides of the second contact unit CTb and on opposite sides of the third contact unit CTc may have resistance components. Hereinafter, for ease of explanation, resistance according to the contact interfaces between the plurality of contact units CTa to CTc and the channel pattern 131 will be defined as the plurality of unit contact resistance (2n)RC.

In some embodiments, the plurality of unit contact resistance (2n)RC may have different values depending on the temperature. For example, the plurality of unit contact resistance (2n)RC may decrease as the temperature rises. In other words, the plurality of unit contact resistance (2n)RC may have negative temperature coefficients of resistance (TCRs).

Meanwhile, between the plurality of contact units CTa to CTc, between the power voltage electrode CT1 and the first contact unit CTa, and between the third contact unit CTc and the sensing electrode CT2, the channel pattern 131 may have drift regions. For example, between the power voltage electrode CT1 and the first contact unit CTa, between the first contact unit CTa and the second contact unit CTb, between the second contact unit CTb and the third contact unit CTc, and between the third contact unit CTc and the sensing electrode CT2, unit drift regions CTR_U may be formed. The unit drift regions CTR_U may have predetermined resistance components. The resistance (n+1)RDU of the unit drift regions CTR_U may have different values depending on the temperature. For example, the resistance (n+1)RDU of the unit drift regions CTR_U may increase as the temperature rises. In other words, the resistance (n+1)RDU of the unit drift regions CTR_U may have negative temperature coefficients of resistance (TCRs).

In this case, the extension length of the first drift region DTR1 may be variously changed. The extension length of the first drift region DTR1 may be determined according to the ratios between the values of the plurality of unit contact resistance (2n)RC and the resistance (n+1)RDU of the plurality of unit drift regions CTR_U. For example, the extension length of the first drift region DTR1 according to some embodiments may be larger than 10 μm; however, the present disclosure is not limited thereto. In order to ensure the extension length of the first drift region DTR1, the channel pattern 131 according to some embodiments may further include portions extending in at least one of the first direction (the X direction) and the second direction (the Y direction). For example, as shown in FIG. 22, when the extension length of the first drift region DTR1 increases, the channel pattern 131 may have bent portions in the peripheral circuit area PA so as to be extend in at least one of the first direction (the X direction) and the second direction (the Y direction).

Further, the extension lengths of the unit drift regions CTR_U may be smaller than the widths of the plurality of contact units CTa to CTc. As an example, as shown in FIGS. 19 to 21, the lengths of the unit drift regions CTR_U in the second direction (the Y direction) may be smaller than the lengths of the plurality of contact units CTa to CTc in the second direction (the Y direction). Accordingly, the resistance value of the second resistive element R2 may decrease as the temperature rises. Here, the extension lengths of the unit drift regions CTR_U may refer to the lengths in the second direction (the Y direction) of portions of the channel pattern 131 positioned between the plurality of contact units CTa to CTc.

Although it is shown in FIGS. 20 and 21 that three contact units CTa to CTc are included, the present disclosure is not limited thereto. For example, as shown in FIG. 22, four contact units CTa to CTd may be included, or two contact units, or five or more contact units may be included.

The semiconductor device according to some embodiments may include the plurality of contact units CTa to CTc, whereby the second resistive element R2 may include the plurality of unit contact resistance (2n)RC having negative temperature coefficients of resistance (TCRs) and the resistance (n+1)RDU of the plurality of unit drift regions CTR_U having positive temperature coefficients of resistance (TCRs). The resistance value of the second resistive element R2 according to the temperature may be easily designed by adjusting the number, interval, and the like of contact units CTa to CTc, whereby the temperature of the semiconductor device may be calculated relatively accurately.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An electronic system comprising:
a semiconductor device; and
a temperature calculator configured to detect a temperature of the semiconductor device,
wherein the semiconductor device includes a main element area and a peripheral circuit area that is positioned on one side of the main element area,
wherein the main element area includes:
a main channel layer,
a barrier layer on the main channel layer and containing a material having an energy band gap different from that of the main channel layer,
a gate electrode on the barrier layer,
a gate semiconductor layer between the barrier layer and the gate electrode, and
a source electrode and a drain electrode positioned on opposite sides of the gate electrode and connected to the main channel layer,
wherein the peripheral circuit area includes:
a channel pattern connected to the source electrode and including drift regions having a two-dimensional electron gas,
a power voltage electrode on the channel pattern and spaced apart from the source electrode, and configured to receive a sensing power voltage, and
a sensing electrode on the channel pattern and between the source electrode and the power voltage electrode,
wherein a resistance of a first drift region of the channel pattern between the source electrode and the sensing electrode has a positive temperature coefficient of resistance,
wherein a first contact resistance between the power voltage electrode and the channel pattern has a negative temperature coefficient of resistance, and
wherein the temperature calculator is configured to receive a sensing voltage from the sensing electrode and sense the temperature of the semiconductor device according to a ratio between a resistance value of the first drift region and a value of the first contact resistance.

2. The electronic system of claim 1, wherein an extension length of the first drift region of the channel pattern is 1 μm to 10 μm.

3. The electronic system of claim 1, wherein a width of the sensing electrode in one direction is smaller than a width of the power voltage electrode in the one direction.

4. The electronic system of claim 1, wherein the channel pattern contains the same material as that of the main channel layer, and the power voltage electrode contains the same material as that of the source electrode.

5. The electronic system of claim 4, wherein the power voltage electrode and the source electrode are positioned apart from each other on the same plane.

6. The electronic system of claim 1,
wherein the barrier layer is on the channel pattern, and
wherein the power voltage electrode and the sensing electrode pass through the barrier layer.

7. The electronic system of claim 6, wherein the channel pattern is formed integrally with the main channel layer.

8. The electronic system of claim 6,
wherein in the main element area, the main channel layer further includes an extension portion between the source electrode and the channel pattern, and
wherein a width of the extension portion is larger than a width of the channel pattern.

9. The electronic system of claim 6, further comprising:
a separation structure on the channel pattern between the peripheral circuit area and the main element area and passing through the barrier layer.

10. The electronic system of claim 1,
wherein the temperature calculator is configured to receive a sensing voltage from the sensing electrode and sense the temperature of the semiconductor device according to a ratio between a sum of the value of the first contact resistance, a resistance value of a second drift region and the resistance value of the first drift region, and
wherein the resistance value of the second drift region corresponds to a resistance of the second drift region of the channel pattern between the power voltage electrode and the sensing electrode.

11. The electronic system of claim 1,
wherein the channel pattern is in contact with one side surface of the source electrode,
wherein the peripheral circuit area further includes main contact resistance between the source electrode and the channel pattern, and
wherein the temperature calculator receives a sensing voltage from the sensing electrode and senses the temperature of the semiconductor device according to a ratio between the sum of the value of the main contact resistance, the resistance value of the first drift region, and the value of the first contact resistance.

12. The electronic system of claim 1,
wherein a width of the sensing electrode in one direction is the same as a width of the channel pattern in the one direction, and
wherein the peripheral circuit area further includes:
second contact resistance between one side of the sensing electrode and the channel pattern, and
third contact resistance between another side of the sensing electrode facing the one side and the channel pattern.

13. A semiconductor device, the device comprising:
a main element area; and
a peripheral circuit area positioned on one side of the main element area,
wherein the main element area includes:
a main channel layer,
a barrier layer on the main channel layer and containing a material having an energy band gap different from that of the main channel layer,
a gate electrode on the barrier layer,
a gate semiconductor layer between the barrier layer and the gate electrode, and
a source electrode and a drain electrode on opposite sides of the gate electrode and connected to the main channel layer,
wherein the peripheral circuit area includes:
a channel pattern connected to the source electrode and including drift regions having a two-dimensional electron gas,
a power voltage electrode on the channel pattern and spaced apart from the source electrode, and configured to receive a sensing power voltage, and
a sensing electrode on the channel pattern and between the source electrode and the power voltage electrode,
wherein a resistance of a first drift region of the channel pattern between the source electrode and the sensing electrode has a positive temperature coefficient of resistance,
wherein a first contact resistance between the power voltage electrode and the channel pattern has a negative temperature coefficient of resistance, and
wherein a width of the channel pattern is smaller than a width of the main channel layer, and a width of the sensing electrode is smaller than the width of the channel pattern.

14. The semiconductor device of claim 13, wherein an extension length of the first drift region is longer than a distance between the sensing electrode and the power voltage electrode.

15. The semiconductor device of claim 14, wherein a ratio of a resistance value of the first drift region to a value of the first contact resistance is equal to or smaller than 6.

16. An electronic system comprising:
a semiconductor device; and
a temperature calculator configured to detect a temperature of the semiconductor device,
wherein the semiconductor device includes a main element area and a peripheral circuit area that is positioned on one side of the main element area,
wherein the main element area includes:
a main channel layer that contains GaN,
a barrier layer on the main channel layer and containing AlGaN,
a gate electrode on the barrier layer,
a gate semiconductor layer between the barrier layer and the gate electrode, and containing GaN doped with a p-type impurity,
a source electrode and a drain electrode positioned on opposite sides of the gate electrode and connected to the main channel layer, and
a protective layer that covers the barrier layer and the gate electrode,
wherein the peripheral circuit area includes:
a channel pattern connected to the source electrode, containing the same material as that of the main channel layer, and including drift regions having a two-dimensional electron gas,
a power voltage electrode on the channel pattern, containing the same material as that of the source electrode, and positioned apart from the source electrode, and
a sensing electrode on the channel pattern and between the source electrode and the power voltage electrode,
wherein a resistance of a first drift region of the channel pattern between the source electrode and the sensing electrode has a positive temperature coefficient of resistance,
wherein a first contact resistance between the power voltage electrode and the channel pattern has a negative temperature coefficient of resistance, and
wherein the temperature calculator is configured to receive a sensing voltage from the sensing electrode and sense the temperature of the semiconductor device according to a ratio between a resistance value of the first drift region and a value of the first contact resistance.

17. The electronic system of claim 16, wherein an extension length of the first drift region of the channel pattern is 1 μm to 10 μm.

18. The electronic system of claim 16,
wherein the temperature calculator is configured to receive a sensing voltage from the sensing electrode and sense the temperature of the semiconductor device according to a ratio between a sum of the value of the first contact resistance, a resistance value of a second drift region, and the resistance value of the first drift region, and
wherein the resistance value of the second drift region corresponds to a resistance of the second drift region of the channel pattern between the power voltage electrode and the sensing electrode.

19. The electronic system of claim 16, wherein the channel pattern is formed integrally with the main channel layer.

20. The electronic system of claim 16, wherein the power voltage electrode, the sensing electrode, and the source electrode are positioned apart from one another on the same plane.
